(19) United States
(12) Patent Application Publication
(10) Pub. No.: US 2025/0385070 A1
(43) Pub. Date: Dec. 18, 2025

(54) SCANNING ELECTRON MICROSCOPY (SEM) BACK-SCATTERING ELECTRON (BSE) FOCUSED TARGET AND METHOD

(71) Applicant: ASML NETHERLANDS B.V., Veldhoven (NL)

(72) Inventors: Jiyou FU, San Jose, CA (US); Cyrus Emil TABERY, San Jose, CA (US); Benoit Herve GAURY, Eindhoven (NL)

(73) Assignee: ASML NETHERLANDS B.V., Veldhoven (NL)

(21) Appl. No.: 18/877,249

(22) PCT Filed: Sep. 21, 2023
(86) PCT No.: PCT/EP2023/076085

§ 371 Date: Dec. 19, 2024

Related U.S. Application Data
(60) Provisional application No. 63/411,863, filed on Sep. 30, 2022.

(51) Int. Cl. H01J 37/244; H01J 37/28

(52) U.S. Cl. CPC H01J 37/244; H01J 37/28; H01J 2237/221; H01J 2237/2826

(57) ABSTRACT

A method for evaluating a scanning electron microscope (SEM) system, the method including accessing an SEM image of two or more sets of overlay targets, wherein each set of overlay targets includes buried features and top features, the buried features at a buried depth, wherein, in at least one of the two or more sets of overlay targets, the top features are recessed, each of the recesses having a corresponding recess depth, wherein the recess depths for the top features of the two or more sets of overlay targets are different; and determining a beam tilt angle of a SEM system based on the SEM image of the two or more sets of overlay targets.

### CROSS-REFERENCE TO RELATED APPLICATIONS

This application claims priority of U.S. application 63/411,863 which was filed on 30 Sep. 2022, and which is incorporated herein in its entirety by reference.

### TECHNICAL FIELD

The present disclosure relates generally to scanning electron microscopy (SEM) system qualification and evaluation, and a method for SEM performance monitoring based on an SEM target structure.

### BACKGROUND

In manufacturing processes of integrated circuits (ICs), unfinished or finished circuit components are inspected to ensure that they are manufactured according to design and are free of defects. Inspection systems utilizing optical microscopes or charged particle (e.g., electron) beam microscopes, such as a scanning electron microscope (SEM) can be employed. As the physical sizes of IC components continue to shrink, and their structures continue to become more complex, accuracy and throughput in defect detection and inspection become more important. The overall image quality depends on a combination of high secondary-electron and backscattered-electron signal detection efficiencies, among others. Backscattered electrons have higher emission energy to escape from deeper layers of a sample, and therefore, their detection may be desirable for imaging of complex structures such as buried layers, nodes, high-aspect-ratio trenches or holes of 3D NAND devices. For applications such as overlay metrology, it may be desirable to obtain high quality imaging and efficient collection of surface information from secondary electrons and buried layer information from backscattered electrons, simultaneously, highlighting a need for using multiple electron detectors in a SEM. The ability to monitor and detect IC non-idealities may be limited by an image quality of the inspection system, including by the alignment or calibration of an SEM system.

In the context of semiconductor manufacture, SEM system alignment and calibration needs to be monitored and qualified.

### SUMMARY

Embodiments of the present disclosure provide designs of SEM targets and systems and methods of processing SEM images thereof to evaluate and qualify a SEM system, e.g., metrology and inspection. Embodiments provide features and SEM target designs which may be used to determine beam tilt angle, resolution, contrast, overlay precision, and other metrics for the SEM system. The SEM system may be adjusted (e.g., aligned) based on the determined metrics, such that SEM image quality may be maintained (e.g., above a threshold) or improved.

According to an embodiment, there is provided a method for evaluating or qualifying a scanning electron microscope (SEM) system, comprising: accessing an SEM image of two or more sets of overlay targets, wherein each overlay target comprises buried features and top features, the buried features at a buried depth, wherein, in at least one of the two or more sets of overlay targets, the top features are recessed, each of the recesses having a corresponding recess depth, wherein the recess depths for the top features of the two or more sets of overlay targets are different; and determining a beam tilt angle of a SEM system based on the SEM image of the two or more sets of overlay targets.

In an embodiment, determining the beam tilt angle comprises determining the beam tilt angle based on set-get relationships for overlay determined (“get”) for the several sets of overlay targets with programmed varying (“set”) overlays.

In an embodiment, determining the beam tilt angle based on the set-get relationships for overlay comprises: obtaining measurements of at least one of the recess depths, a difference between the recess depths, or a combination thereof; determining intercept values based on fitting of the set-get relationships for overlay for the two or more sets of overlay targets; and determining the beam tilt angle based on the intercept values and the measurements of at least one of recess depths, a difference between the recess depths, or a combination thereof.

According to another embodiment, there is provided a method for evaluating a scanning electron microscope (SEM) system, comprising: accessing a SEM image of a plurality of cells of containing various patterns, wherein each cell within the plurality comprises a pattern having a certain pitch, wherein the pattern comprises buried features at a certain buried depth, and wherein the SEM image comprises an image of the plurality of cells within a single field of view (FOV); and determining, for at least one of the cells within the single FOV, a relationship between the pitch thereof and at least one of contrast, resolution, or a combination thereof.

According to another embodiment, a method is provided for evaluating or qualifying a scanning electron microscope (SEM) system comprising: accessing SEM images of a plurality of cells containing various patterns, wherein each cell within the plurality comprises a pattern having a certain pitch, wherein the pattern comprises buried features and top features separated by a buried depth, wherein the buried features and the top features are separated by an overlay offset in a direction perpendicular to the buried depth, wherein the certain pitch varies among at least some of the plurality of cells, and wherein the SEM images comprise images of the plurality of cells within a single field of view (FOV); and determining a relationship between pitch and overlay precision based on the SEM images of the plurality of cells having corresponding pitches.

According to another embodiment, a measurement structure is provided for evaluation or qualification of a scanning electron microscope (SEM). The structure comprises: a plurality of areas on a wafer, each area containing buried features, the buried features having a measurable structural characteristic, wherein the buried features are buried under top features, the buried features having certain buried depths, wherein at least some of the top features are recessed, the top features having corresponding recess depths, wherein a first set of areas comprise a first overlay target and a second set of areas comprise a second overlay target, wherein the recess depth for the first overlay target and the recess depth for the second overlay target are different, and wherein the first overlay target and the second overlay target are adjacent to one another.

According to another embodiment, an SEM target for evaluation of an SEM system is provided, where the SEM target comprises a plurality of areas on a wafer, each area containing buried features, the buried features having a measurable structural characteristic, wherein the buried features are buried under top features, the buried features having corresponding buried depths, wherein at least some of the top features are recessed, the top features having corresponding recess depths, wherein a first set of areas comprise a first set of programmed overlay targets and a second set of areas comprise a second set of programmed overlay targets, wherein the recess depth for the first set of programmed overlay targets and the recess depth for the second set of programmed overlay targets are different, and wherein the first overlay target and the second overlay target are adjacent to one another.

According to another embodiment, a method is provided for fabrication of the measurement structures of any other embodiment.

According to another embodiment, one or more non-transitory, machine-readable medium is provided having instructions thereon, the instructions when executed by a processor being configured to fabricate the measurement structure of any other embodiment.

### BRIEF DESCRIPTION OF THE DRAWINGS

The accompanying drawings, which are incorporated in and constitute a part of the specification, illustrate one or more embodiments and, together with the description, explain these embodiments. Embodiments of the invention will now be described, by way of example only, with reference to the accompanying schematic drawings in which corresponding reference symbols indicate corresponding parts, and in which:

FIG. 1 is a schematic diagram illustrating an exemplary electron beam inspection (EBI) system, according to an embodiment.

FIG. 2 is a schematic diagram of an exemplary electron beam tool, according to an embodiment.

FIG. 3 depicts a schematic representation of holistic lithography, representing a cooperation between three technologies to optimize semiconductor manufacturing, according to an embodiment.

FIG. 4 depicts a schematic representation of an example SEM target, according to an embodiment.

FIGS. 5A-5B depict views of buried features in an example SEM target, according to an embodiment.

FIGS. 6A-6C depict example graphs of a relationship between contrast and landing energy for buried features of various buried depths, according to an embodiment.

FIG. 7 depicts an example graph of a measured relationship between contrast and landing energy for a SEM target comprising buried features, according to an embodiment.

FIG. 8 illustrates a method of SEM evaluation based on a SEM target comprising buried features of various pitches, according to an embodiment.

FIGS. 9A-9B depict views of overlay features in an example SEM target, according to an embodiment.

FIG. 10 depicts example overlay relationships in an example SEM target, according to an embodiment.

FIGS. 11A-11C depict example graphs of a relationship between precision and landing energy for a SEM target comprising overlay features, according to an embodiment.

FIGS. 12A-12B depict views of tilt angle calibration features in an example SEM target, according to an embodiment.

FIGS. 13A-13B depict views of tilt angle calibration features with recesses in an example SEM target, according to an embodiment.

FIGS. 14A-14B depict tilt angle calibration features for a SEM target, according to an embodiment.

FIG. 15 depicts an example graph of a set-get relationship between overlay acquired using tilt angle calibration features of a SEM target, according to an embodiment.

FIG. 16 illustrates a method of SEM target generation, according to an embodiment.

FIG. 17 is a block diagram of an example computer system, according to an embodiment of the present disclosure.

### DETAILED DESCRIPTION

Embodiments of the present disclosure are described in detail with reference to the drawings, which are provided as illustrative examples of the disclosure so as to enable those skilled in the art to practice the disclosure. Notably, the figures and examples below are not meant to limit the scope of the present disclosure to a single embodiment, but other embodiments are possible by way of interchange of some or all of the described or illustrated elements. Moreover, where certain elements of the present disclosure can be partially or fully implemented using known components, only those portions of such known components that are necessary for an understanding of the present disclosure will be described, and detailed descriptions of other portions of such known components will be omitted so as not to obscure the disclosure. Embodiments described as being implemented in software should not be limited thereto, but can include embodiments implemented in hardware, or combinations of software and hardware, and vice-versa, as will be apparent to those skilled in the art, unless otherwise specified herein. In the present specification, an embodiment showing a singular component should not be considered limiting; rather, the disclosure is intended to encompass other embodiments including a plurality of the same component, and vice-versa, unless explicitly stated otherwise herein. Moreover, applicants do not intend for any term in the specification or claims to be ascribed an uncommon or special meaning unless explicitly set forth as such. Further, the present disclosure encompasses present and future known equivalents to the known components referred to herein by way of illustration.

Although specific reference may be made in this text to the manufacture of ICs, it should be explicitly understood that the description herein has many other possible applications. For example, it may be employed in the manufacture of integrated optical systems, guidance and detection patterns for magnetic domain memories, liquid-crystal display panels, thin-film magnetic heads, etc. The skilled artisan will appreciate that, in the context of such alternative applications, any use of the terms “wafer” or “die” in this text should be considered as interchangeable with the more general terms “substrate” and “target portion”, respectively.

A patterning device can comprise, or can form, one or more patterns. The patterns can be generated utilizing CAD (computer-aided design) programs, based on a pattern or design layout, this process often being referred to as EDA (electronic design automation).

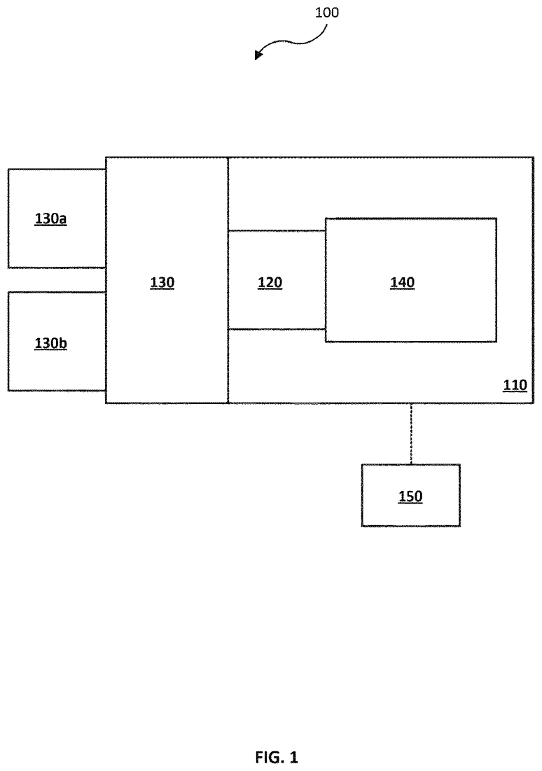

Reference is now made to FIG. 1, which illustrates an exemplary electron beam inspection (EBI) system 100 consistent with embodiments of the present disclosure. As shown in FIG. 1, EBI system 100 includes a main chamber 110, a load-lock chamber 120, an electron beam tool 140, and an equipment front end module (EFEM) 130. Electron beam tool 140 is located within main chamber 110. The exemplary EBI system 100 may be a single or multi-beam system. While the description and drawings are directed to an electron beam, it is appreciated that the embodiments are not used to limit the present disclosure to specific charged particles.

EFEM 130 includes a first loading port 130a and a second loading port 130b. EFEM 130 may include additional loading port(s). First loading port 130a and second loading port 130b receive wafer front opening unified pods (FOUPs) that contain wafers (e.g., semiconductor wafers or wafers made of other material(s)) or samples to be inspected (wafers and samples are collectively referred to as “wafers” hereafter). One or more robot arms (not shown) in EFEM 130 transport the wafers to load-lock chamber 120.

Load-lock chamber 120 is connected to a load/lock vacuum pump system (not shown), which removes gas molecules in load-lock chamber 120 to reach a first pressure below the atmospheric pressure. After reaching the first pressure, one or more robot arms (not shown) transport the wafer from load-lock chamber 120 to main chamber 110. Main chamber 110 is connected to a main chamber vacuum pump system (not shown), which removes gas molecules in main chamber 110 to reach a second pressure below the first pressure. After reaching the second pressure, the wafer is subject to inspection by electron beam tool 140. In some embodiments, electron beam tool 140 may comprise a single-beam inspection tool.

Controller 150 may be electronically connected to electron beam tool 140 and may be electronically connected to other components as well. Controller 150 may be a computer configured to execute various controls of EBI system 100. Controller 150 may also include processing circuitry configured to execute various signal and image processing functions. While controller 150 is shown in FIG. 1 as being outside of the structure that includes main chamber 110, load-lock chamber 120, and EFEM 130, it is appreciated that controller 150 can be part of the structure.

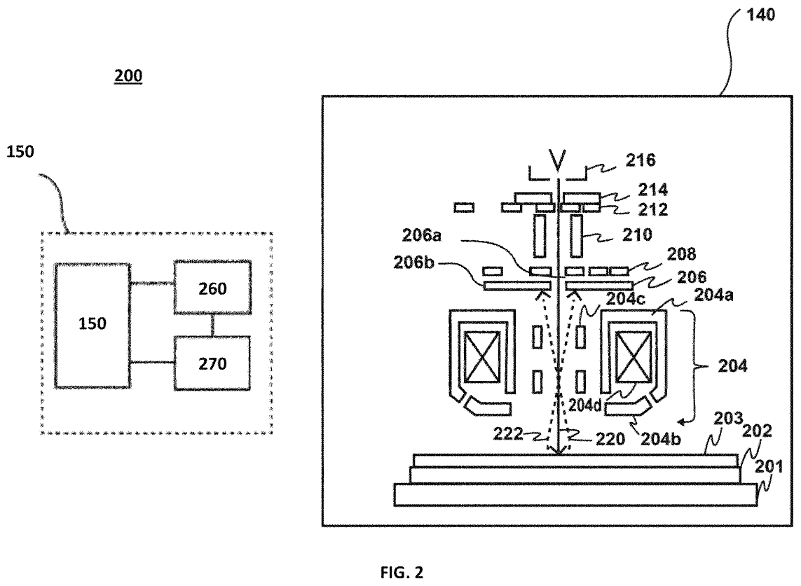

FIG. 2 illustrates schematic diagram of an exemplary imaging system 200 according to embodiments of the present disclosure. Electron beam tool 140 of FIG. 2 may be configured for use in EBI system 100. Electron beam tool 140 may be a single beam apparatus or a multi-beam apparatus. As shown in FIG. 2, electron beam tool 140 includes a motorized sample stage 201, and a wafer holder 202 supported by motorized sample stage 201 to hold a wafer 203 to be inspected. Electron beam tool 140 further includes an objective lens assembly 204, an electron detector 206 (which includes electron sensor surfaces 206a and 206b), an objective aperture 208, a condenser lens 210, a beam limit aperture 212, a gun aperture 214, an anode 216, and a cathode 218. Objective lens assembly 204, in some embodiments, may include a modified swing objective retarding immersion lens (SORIL), which includes a pole piece 204a, a control electrode 204b, a deflector 204c, and an exciting coil 204d. Electron beam tool 140 may additionally include an Energy Dispersive X-ray Spectrometer (EDS) detector (not shown) to characterize the materials on wafer 203.

A primary electron beam 220 is emitted from cathode 218 by applying a voltage between anode 216 and cathode 218. Primary electron beam 220 passes through gun aperture 214 and beam limit aperture 212, both of which may determine the size of electron beam entering condenser lens 210, which resides below beam limit aperture 212. Condenser lens 210 focuses primary electron beam 220 before the beam enters objective aperture 208 to set the size of the electron beam before entering objective lens assembly 204. Deflector 204c deflects primary electron beam 220 to facilitate beam scanning on the wafer. For example, in a scanning process, deflector 204c may be controlled to deflect primary electron beam 220 sequentially onto different locations of top surface of wafer 203 at different time points, to provide data for image reconstruction for different parts of wafer 203. Moreover, deflector 204c may also be controlled to deflect primary electron beam 220 onto different sides of wafer 203 at a particular location, at different time points, to provide data for stereo image reconstruction of the wafer structure at that location. Further, in some embodiments, anode 216 and cathode 218 may be configured to generate multiple primary electron beams 220, and electron beam tool 140 may include a plurality of deflectors 204c to project the multiple primary electron beams 220 to different parts/sides of the wafer at the same time, to provide data for image reconstruction for different parts of wafer 203.

Exciting coil 204d and pole piece 204a generate a magnetic field that begins at one end of pole piece 204a and terminates at the other end of pole piece 204a. A part of wafer 203 being scanned by primary electron beam 220 may be immersed in the magnetic field and may be electrically charged, which, in turn, creates an electric field. The electric field reduces the energy of impinging primary electron beam 220 near the surface of wafer 203 before it collides with wafer 203. Control electrode 204b, being electrically isolated from pole piece 204a, controls an electric field on wafer 203 to prevent micro-arching of wafer 203 and to ensure proper beam focus.

A secondary electron beam 222 may be emitted from the part of wafer 203 upon receiving primary electron beam 220. Secondary electron beam 222 may form a beam spot on sensor surfaces 206a and 206b of electron detector 206. Electron detector 206 may generate a signal (e.g., a voltage, a current, etc.) that represents an intensity of the beam spot, and provide the signal to an image processing system 250. The intensity of secondary electron beam 222, and the resultant beam spot, may vary according to the external or internal structure of wafer 203. Moreover, as discussed above, primary electron beam 220 may be projected onto different locations of the top surface of the wafer or different sides of the wafer at a particular location, to generate secondary electron beams 222 (and the resultant beam spot) of different intensities. Therefore, by mapping the intensities of the beam spots with the locations of wafer 203, the processing system may reconstruct an image that reflects the internal or surface structures of wafer 203.

Imaging system 200 may be used for inspecting a wafer 203 on sample stage 201, and comprises an electron beam tool 140, as discussed above. Imaging system 200 may also comprise an image processing system 250 that includes an image acquirer 260, storage 270, and controller 150. Image acquirer 260 may comprise one or more processors. For example, image acquirer 260 may comprise a computer, server, mainframe host, terminals, personal computer, any kind of mobile computing devices, and the like, or a combination thereof. Image acquirer 260 may connect with a detector 206 of electron beam tool 140 through a medium such as an electrical conductor, optical fiber cable, portable storage media, IR, Bluetooth, internet, wireless network, wireless radio, or a combination thereof. Image acquirer 260 may receive a signal from detector 206 and may construct an image. Image acquirer 260 may thus acquire images of wafer 203. Image acquirer 260 may also perform various post-processing functions, such as generating contours, superimposing indicators on an acquired image, and the like. Image acquirer 260 may be configured to perform adjustments of brightness and contrast, etc. of acquired images. Storage 270 may be a storage medium such as a hard disk, cloud storage, random access memory (RAM), other types of computer readable memory, and the like. Storage 270 may be coupled with image acquirer 260 and may be used for saving scanned raw image data as original images, and post-processed images. Image acquirer 260 and storage 270 may be connected to controller 150. In some embodiments, image acquirer 260, storage 270, and controller 150 may be integrated together as one control unit.

In some embodiments, image acquirer 260 may acquire one or more images of a sample based on an imaging signal received from detector 206. An imaging signal may correspond to a scanning operation for conducting charged particle imaging. An acquired image may be a single image comprising a plurality of imaging areas. The single image may be stored in storage 270. The single image may be an original image that may be divided into a plurality of regions. Each of the regions may comprise one imaging area containing a feature of wafer 203.

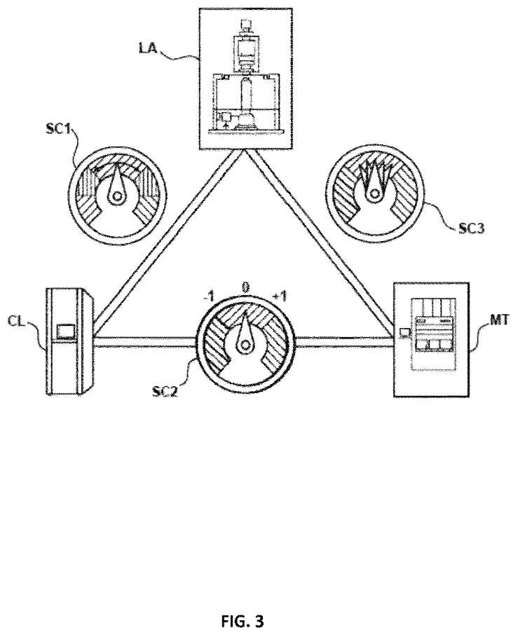

FIG. 3 depicts a schematic representation of holistic lithography, representing a cooperation between three technologies to optimize semiconductor manufacturing. Typically, the patterning process in a lithographic apparatus LA is one of the most critical steps in the processing which requires high accuracy of dimensioning and placement of structures on the substrate W (FIG. 1). To ensure this high accuracy, three systems (in this example) may be combined in a so called “holistic” control environment as schematically depicted in FIG. 3. One of these systems is the lithographic apparatus LA which is (virtually) connected to a metrology apparatus (e.g., a metrology tool) MT (a second system), and to a computer system CL (a third system). A “holistic” environment may be configured to optimize the cooperation between these three systems to enhance the overall process window and provide tight control loops to ensure that the patterning performed by the lithographic apparatus LA stays within a process window. The process window defines a range of process parameters (e.g., dose, focus, overlay) within which a specific manufacturing process yields a defined result (e.g., a functional semiconductor device)—typically within which the process parameters in the lithographic process or patterning process are allowed to vary.

The computer system CL may use (part of) the design layout to be patterned to predict which resolution enhancement techniques to use and to perform computational lithography simulations and calculations to determine which mask layout and lithographic apparatus settings achieve the largest overall process window of the patterning process (depicted in FIG. 2 by the double arrow in the first scale SC1). Typically, the resolution enhancement techniques are arranged to match the patterning possibilities of the lithographic apparatus LA. The computer system CL may also be used to detect where within the process window the lithographic apparatus LA is currently operating (e.g., using input from the metrology tool MT) to predict whether defects may be present due to, for example, sub-optimal processing (depicted in FIG. 2 by the arrow pointing “0” in the second scale SC2).

The metrology apparatus (tool) MT may provide input to the computer system CL to enable accurate simulations and predictions, and may provide feedback to the lithographic apparatus LA to identify possible drifts, e.g., in a calibration status of the lithographic apparatus LA (depicted in FIG. 3 by the multiple arrows in the third scale SC3).

In lithographic processes, it is desirable to make frequent measurements of the structures created, e.g., for process control and verification. Different types of metrology tools MT for making such measurements are known, including scanning electron microscopes or various forms of optical metrology tool, image based or scatterometery-based metrology tools. Image analysis on images obtained from optical metrology tools and scanning electron microscopes can be used to measure various dimensions (e.g., CD, overlay, edge placement error (EPE) etc.) and detect defects for the structures. In some cases, a feature of one layer of the structure can obscure a feature of another or the same layer of the structure in an image. This can be the case what one layer is physically on top of another layer, or when one layer is electronically rich and therefore brighter than another layer in a scanning electron microscopy (SEM) image, for example. In cases where a feature is partially obscured in an image, the location of the image can be determined based on template matching.

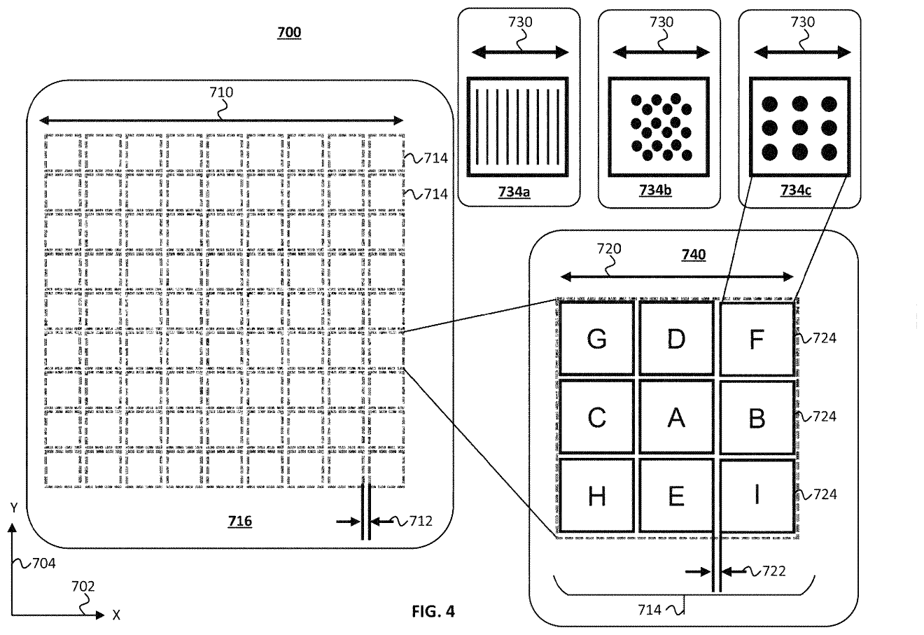

FIG. 4 depicts a schematic representation 700 of an example SEM target comprising a plurality of areas. The schematic representation 700 is depicted with respect to an x-axis 702 and a y-axis 704, which represent directions in a plane substantially parallel to a fabrication surface (e.g., a wafer surface). Herein, a generic x-axis and generic y-axis are provided to aid in the description of elements in a plane parallel to a fabrication surface, while a generic z-axis is used to describe a direction substantially perpendicular to a fabrication surface (e.g., a direction of fabrication). The axes are presented for ease of description only, where fabrication need not be performed in a plane, on a substantially flat surface, substantially perpendicular to a surface, etc. Fabrication processes are not limited to those described by these axes, which are provided for ease of description only. These axes can instead be represented by polar coordinates, cylindrical coordinates, different orientations of Cartesian coordinates, etc.

The schematic representation 700 includes an overview of a SEM target 716, which comprises a plurality of areas 714 (e.g., cells). The SEM target 716 is depicted as a rectilinear array of a plurality of areas 714, but can instead be comprised of a set of areas organized along less than perpendicular axes (e.g., as a set of parallelograms). The SEM target 716 is depicted as comprising a plurality of areas 714 which are separated by a distance 712. The SEM target 716 can instead comprise a plurality of areas 714 which are separated by a variety of distances, interspersed, etc. which may or may not have linear edges. The SEM target 716 can be symmetric in size (e.g., square) along each of its major dimensions, or can be rectangular, circular, oblong, etc. The SEM target 716 may fit within a single field of view of an SEM system used to acquire an SEM image. The SEM target 716 may have a size 710, which, for example, may be 20 μm. The SEM target 716 may have a size 710 which corresponds to an SEM FOV—for example, 16 μm, 40 μm, etc. The size 710 may be the same or different for the major dimensions (e.g., the x-axis 702 and the y-axis 704 as depicted). For example, the distance 712 which separates the areas 714 may be 0.2 μm, while the areas 714 may have dimensions of 2.0 μm. These dimensions are provided as an example, and the SEM target 716, distance 712, and areas 714 may have larger or smaller dimensions depending on applications, e.g., including eight times as large as described or as small as a minimal feature size of a process layer. The areas 714 are depicted enclosed by a boundary, but may or may not have a boundary feature (e.g., a linear fabricated feature such as a trench or berm, fabricated orientation patterns, etc.). A boundary feature, which may or may not vary based on location within the SEM target 716, may be used to orient or navigate to a portion of an SEM image of the SEM target 716.

The areas 714 of the SEM target 716 may be substantially similar—e.g., may contain similar features including similar features which vary in size. The areas 714 of the SEM target 716 may instead be different—e.g., may contain different features including features which may be used for different purposes such as alignment along different axes. For example, the areas 714 may contain different types of features (e.g., buried features, top features, recessed features, etc.), different orientation of features (e.g., oriented along the x-axis 702, along the y-axis 704, oriented in a rectilinear array, staggered, etc.), features of different measurable structural characteristics (e.g., pitch, feature separation, buried depth, lateral offset, etc.), etc. The areas 714 may contain a mixture of features which are substantially similar in some respect, but different in other respects. For example, the areas 714 may contain a repeating set of features which have different pitches in different ones of the areas 714. The areas 714 may contain various features, such as features (e.g., tilt angle calibration features) for measuring beam tilt angle (e.g., telecentricity angle), features for measuring resolution, contrast, or a combination of resolution and contrast, features for measuring overlay precision, etc. The areas 714 of the SEM target 716 may be further divided into areas or may comprise undivided areas.

A detailed view 740 of an instance of the area 714 is also shown, where the detailed view 740 is at a different, larger scale, than that of the SEM target 716 in the schematic representation 700. The detailed view 740 depicts an area 714 which may be further divided into a plurality of areas 724 (e.g., cells). The term areas is used to refer to both subunits of the SEM target 716 and subunits of the area 714, where such terms are used for ease of description only, but different terms for the comprising units may be used instead, such as areas and subareas, regions and areas, etc. The area 714 is depicted as a rectilinear array of areas 724, but may instead be comprised of a set of areas organized along less than perpendicular axes (e.g., as a set of parallelograms). The area 714 is depicted as comprising a plurality of areas 724 which are separated by a distance 722. The area 714 may instead comprise a plurality of areas 724 which are separated by a variety of distances, interspersed, etc. which may or may not have linear edges. The area 714 may be symmetric in size (e.g., square) along each of its major dimensions, or can be rectangular, circular, oblong, etc. The area 714 may fit within a single field of view of an SEM system when used to acquire an SEM image. The area 714 may have a size 720, which, for example, may be 2 μm. The size 720 may be the same or different for the major dimensions (e.g., the x-axis 702 and the y-axis 704 as depicted). For example, the distance 722 which separates the areas 724 may be 0.1 μm, while the areas 724 may have dimensions of 0.6 μm. These dimensions are provided as an example, and the areas 724, distance 722, and areas 724 may have larger or smaller dimensions depending on applications, e.g., including eight times as large as described or as small as a minimal feature size of a process layer. The areas 724 are depicted enclosed by a boundary, but may or may not have a boundary feature. A boundary feature may be used to orient or navigate to a portion of an SEM image of the SEM target 716. A boundary of an area 724 may comprise part of a boundary of an area 714 or may be in addition to a boundary of an area 714.

In some embodiments, the sub-areas 724 of the areas 714 may be substantially similar. In some embodiments, the sub-areas 724 may instead be different. For example, the areas 724 may contain different types of features (e.g., buried features, top features, recessed features, offset features, etc.), different orientation of features (e.g., oriented along the x-axis 702, along the y-axis 704, oriented in a rectilinear array, staggered, etc.), features of different measurable structural characteristics (e.g., pitch, feature separation, buried depth, lateral offset, etc.), etc. In some embodiments, the areas 724 may contain a mixture of features which are substantially similar in some respect, but different in other respects. For example, the areas 724 may contain a repeating set of features which have different pitches in different ones of the areas 724. In another example, some of the areas 724 may contain a repeating set of features which have different orientations (for example, of a long axis of a rectangular feature) in different ones of the areas 724. The areas 724 may together contain various features which may comprise features for measuring beam tilt angle, features for measuring resolution, contrast, or a combination of resolution and contrast, features for measuring overlay precision, etc.

An example relationship between the areas 724 of the area 714 is also depicted, where roman characters A-I represent placement locations for various of the areas 724. In some embodiments, the areas 724 may have a variety of measurable structural characteristics. In some embodiments, the area 724 with a smallest measurable structural characteristic of the variety of measurable structural characteristics (e.g., a smallest pitch of a variety of pitches) may be placed at the center of the area 714 (e.g., in the area 724A). Areas 724 with measurable structural characteristics which are larger than the smallest measurable structural characteristic may be placed surrounding the center of the area 714 (e.g., in the areas 724B-724I). In some embodiments, the measurable structural characteristics may vary between many of the areas 724. In an example, a size of the measurable structural characteristics of the areas 724 may increase in a predetermined pattern, such as from 724A to 724B to 724C to 724E to 724D to 724F to 724G to 724G. The relationship between areas depicted by roman characteristics A-I is provided as an example, and other relationships and orientations may be used instead.

Detailed views 734a-734c of multiple instances of the area 724 are also shown, where the detailed view 734a-734c correspond to some of the possible orientations of the area 724. The detailed views 734a-734c are depicted at a different, larger scale than that of the SEM target 716 and at a different, larger scale that the detailed view 740 of the area 714. The detailed view 734a depicts a one-dimensional (e.g., line) pattern. The detailed view 734b depicts a two-dimensional (e.g., contact hole pattern), where the two-dimensional features are staggered. The detailed view 734c depicts a two-dimensional (e.g., contact hole pattern), where the two-dimensional features are arrayed but not staggered. The detailed views 734a-734c depict features which may correspond to buried features, top features, recessed features, etc. The detailed views 734a-734c do not obviously depict features of different types, depths, sizes, etc. within a single area 724; however, the areas 724 may contain features of multiple types, depths, sizes, etc. such as overlaying features, recessed and top features, features with different orientation, etc. The detailed view 734a-734c are provided as examples only, and other feature arrangements may be used.

The areas 724 are depicted as a rectilinear, but may instead be comprised of areas with less than perpendicular axes (e.g., as a set of parallelograms). The areas 724 may be symmetric in size (e.g., square) along each major dimension, or can be rectangular, circular, oblong, etc. The areas 724 may fit within a single field of view of an SEM system used to acquire an SEM image. The areas 724 may have a size 730, which, for example, may be 0.6 μm. The size 730 may be the same or different for the major dimensions (e.g., the x-axis 702 and the y-axis 704 as depicted). The features of the areas 724 may have various sizes, including sizes which may be the same of different for the major dimensions of the areas 724. The number of features of the areas 724 may correspond to the size of the features of the areas 724. For example, for one-dimensional features (e.g., lines) with a line width of 60 nm an area 724 of size 730 of 0.6 μm may contain ten features (e.g., where the total dimension in one direction is 0.6 μm which for a feature of 60 nm comprises space for 10 total features). In another example, two-dimensional features (e.g., contact holes) may have dimensions of 45 nm, such as in an arrayed but not staggered pattern. In another example, two-dimensional features (e.g., contact holes) may have dimensions of 30 nm, such as in a staggered pattern. The size and shape of the features of the areas 724 may correspond to features of production devices for which the SEM device is used. For example, features with a smallest measurable structural characteristic may correspond to a CD, orientation, dimensionality, etc. of a production feature. These dimensions are provided as an example, and the areas 724 and the features of the areas 724 may have larger or smaller dimensions depending on applications, e.g., including eight as large as described or as small as a minimal feature size of a process layer. The areas 724 are depicted enclosed by a boundary, but may or may not have a boundary feature (e.g., a linear fabricated feature such as a trench or berm, fabricated orientation patterns, etc.). A boundary feature, which may or may not vary based on location within the SEM target 716, may be used to orient or navigate to a portion of an SEM image of the SEM target 716.

The areas 724 of the SEM target 716 may be substantially similar—e.g., may contain similar features including similar features which vary in size. The areas 724 of the SEM target 716 may instead be different—e.g., may contain different features which may be used for different purposes, such as alignment along different axes. For example, the areas 724 may contain different types of features (e.g., buried features, top features, recessed features, etc.), different orientation of features (e.g., oriented along the x-axis 702, along the y-axis 704, oriented in a rectilinear array, staggered, etc.), features of different measurable structural characteristics (e.g., pitch, feature separation, buried depth, lateral offset, etc.), etc. The areas 724 may contain a mixture of features which are substantially similar in some respect, but different in other respects. For example, the areas 724 may contain a repeating set of features which have different pitches in different ones of the areas 724. The areas 724 may contain various features, such as features (e.g., tilt angle calibration features) for measuring beam tilt angle, features for measuring resolution, contrast, or a combination of resolution and contrast, features for measuring overlay precision, etc.

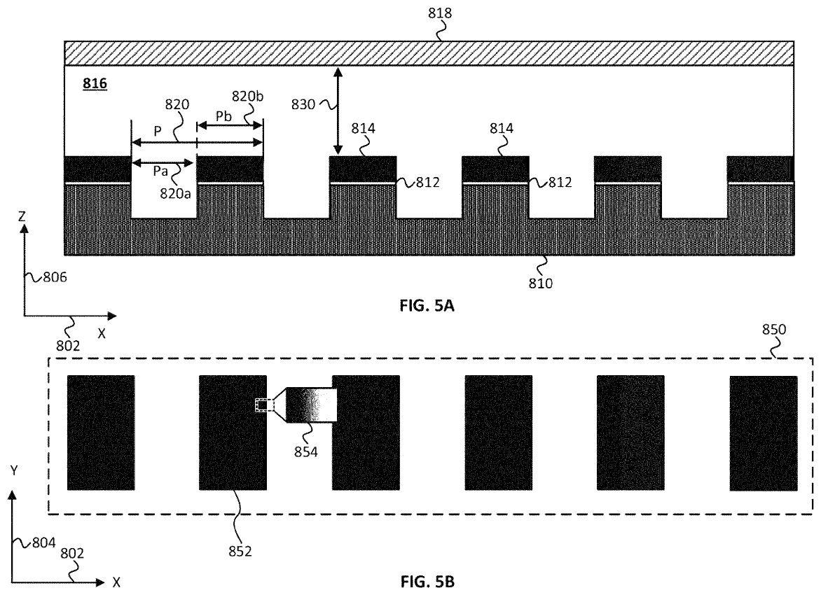

FIGS. 5A-5B depict views of buried features in an example SEM target. FIG. 5A depicts a cross-sectional view of the example SEM target, depicted with respect to a z-axis 806 and an x-axis 802. As with other generic axis described herein, the generic axes are provided for ease of description. The example SEM target may comprise a substrate 810 (which may instead be a bottom layer, bulk layer, etc., such as silicon-on-insulator), a buried feature layer 814, a fill layer 816, and a top layer 818. Interfaces between layers may comprise one or more adhesion or interstitial layer, such as adhesion layer 812 depicted between the substrate 810 and the buried feature layer 814.

The substrate 810 may be etched or otherwise patterned, such as during a process which creates features in the buried feature layer 814. In some embodiments, the substrate 810 may be unpatterned. The buried feature layer 814 may comprise features (e.g., one-dimensional features, two-dimensional features, etc.) with measurable structural characteristics. The buried feature layer 814 may comprise features with a pitch 820, where the pitch 820 is depicted along the x-axis 802 for ease of description. The pitch 820 may be symmetric, where features of the buried feature layer 814 may have a substantially similar feature size 820b and feature separation 820a. In some embodiments, the pitch 820 may be asymmetric, where the features of the buried feature layer 814 may have a feature size 820b and feature separation 820a which differ. The buried feature layer 814 may be located at a buried depth 830. The buried depth 830 may correspond to depth, such as a depth of electron penetration, for an SEM. The buried depth 830 may be selected before fabrication of the SEM target (e.g., selected during design of a fabrication process for an SEM target) based on a corresponding depth of a feature of a production wafer. The buried depth 830 may be selected before fabrication of the SEM target, such as based on a depth corresponding to a landing energy (LE) for an SEM to be used in measurement of production wafers, where depth of electron penetration may vary based on LE. Based on the buried depth 830, a corresponding landing energy (LE) may be selected for SEM imaging of the SEM target, where depth of electron penetration is a function of LE. The buried depth 830 may include a depth of the top layer 818 or may measure the distance between a top of the buried feature layer 814 and a top of the fill layer 816. In some embodiments, the top layer 818 may be omitted or may be substantially included in the fill layer 816. The substrate 810 may be grounded, including via a backside electrode or metal layer, or otherwise provided with a source of electrons.

The materials which comprise the substrate 810, the buried feature layer 814, the fill layer 816, and the top layer 818 may have different SEM characteristics. For example, the substrate 810 and the buried feature layer 814 may have contrasting SEM imaging characteristics, such as backscattering coefficient n, secondary electron yield 8, etc. The substrate 810 and the buried feature layer 814 may have contrasting brightness, such as due to contrasting material type or conductivity (e.g., metal versus semiconductor), atomic number (e.g., titanium versus silicon), etc. The fill layer 816 and the top layer 818 may be less sensitive or less detectable in SEM imaging, including in BSE response.

FIG. 5B depicts a substrate-plane view of an example SEM target (e.g., as depicted in FIG. 5A), depicted with respect to the x-axis 802 and a y-axis 804. As with other generic axis described herein, the generic axes are provided for ease of description. A dashed rectangle 850 encloses features 852 of the example SEM target. The dashed rectangle 850 may enclose an area corresponding to an area of SEM target, such as the areas 724 of FIG. 4. The dashed rectangle 850 is depicted as a polygon pattern. The features 852 may correspond to features of the buried feature layer (e.g., the buried feature layer 814 of FIG. 5A). The features 852 are depicted as rectangles, but may comprise other features, such as contact holes, lines, irregular features, etc.

The dashed rectangle 850 may correspond to an SEM image of the example SEM target. The SEM image may contain areas (e.g., regions of pixels) which correspond to signals from the buried feature layer (e.g., the buried feature layer 814 of FIG. 5A), such as to the features 852. The SEM image may contain areas (e.g., regions of pixels) which correspond to signals from the substrate (e.g., the substrate 810 of FIG. 5A). The SEM image may contain areas which contain signals which correspond to other layers of the example SEM target (e.g., the fill layer 816, the top layer 818, etc.) which may be patterned or unpatterned. A level of contrast for the SEM image may be determined based on the intensity of various areas of the SEM image. For example, a ratio of contrast to noise may be determined. In another example, a change in contrast per pixel may be determined. The level of contrast may be determined based on a difference between an area of the SEM image which corresponds to a buried feature (e.g., to the features 852) and an area of the SEM image which does not correspond to a buried feature. An enlargement of the SEM image corresponding to the example SEM target is shown in rectangle 854. In the illustrative example, the features 852 appear as black pixels in the SEM image, while areas of the example SEM target other than the features 852 correspond to white pixels in the SEM image. These pixel values are provided for ease of description only, and pixel contrast may be lower (e.g., dark gray and light gray) or even inverted (e.g., where the features 852 are brighter than a background). Contrast may be measured as a difference between the pixel values of the features 852 and other regions and/or as a change rate between pixels corresponding to the features 852 and the other regions. The rectangle 854 shows an example rate of change between black pixels of the features 852 and white pixels of other regions. The contrast may be determined for multiple features or areas, such as features corresponding to multiple areas (such as the areas 724 of FIG. 4) of the same or different SEM targets. The contrast may be determined for multiple sets of features, where at least some of the features or sets of features have different measurable structural characteristics. In some cases, a contrast may not be determined for one or more areas, such as if the SEM image is not clear enough to differentiate between buried features or between buried features and regions outside of the buried features. The contrast may be a function of measurable structural characteristics, such as pitch, buried depth, feature size, etc. The contrast may be a function of SEM parameters, such as LE, beam spot size, detector type, etc.

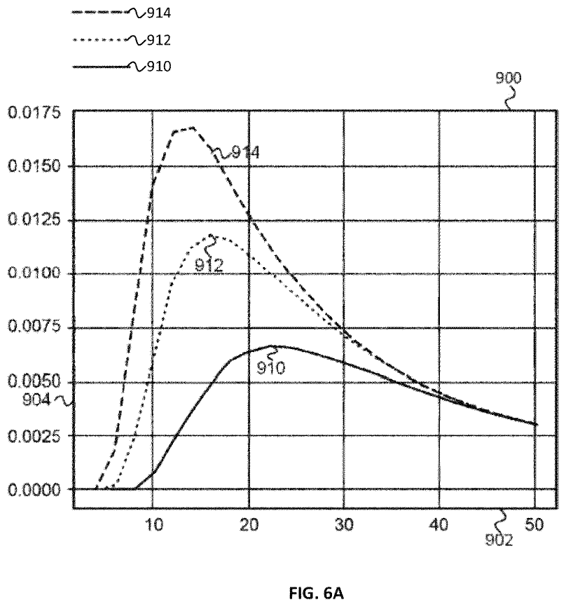

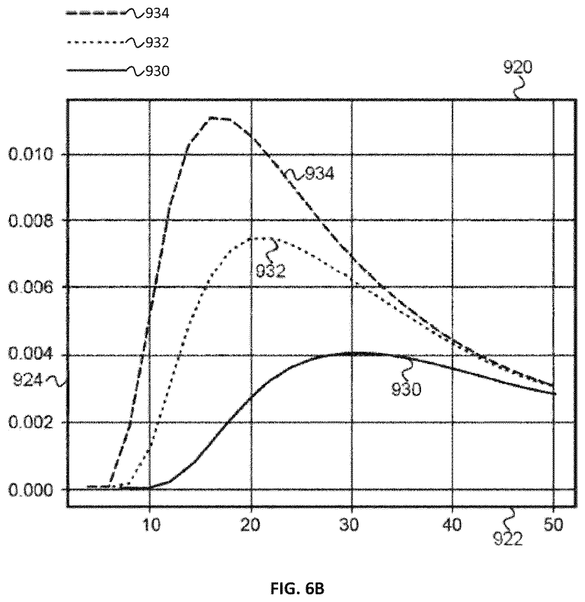

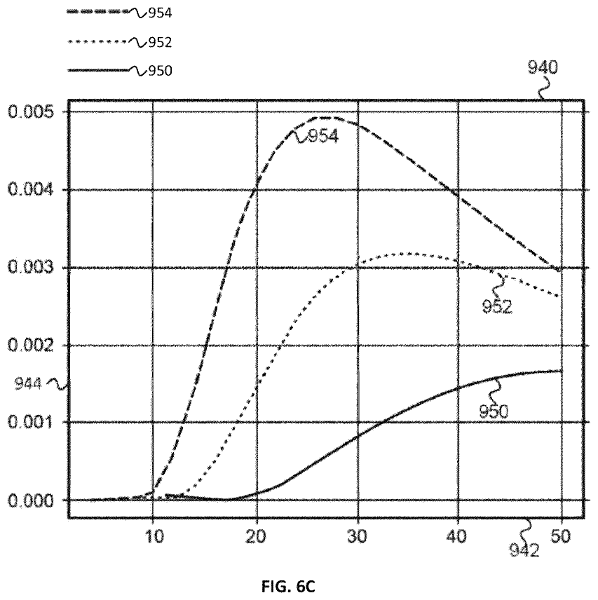

FIGS. 6A-6C depict example graphs of a relationship between contrast and landing energy for buried features of various buried depths. FIG. 6A depicts a graph 900 which depicts contrast (as a contrast to noise ratio along an axis 904) as a function of LE (in kilo electron volts (keV) along an axis 902). The graph 900 shows a line 910 corresponding to a set of features (such as depicted in FIGS. 5A and 5B) of an SEM target with a pitch of 30 nm and a buried depth of 30 nm. The graph 900 shows a dotted line 912 corresponding to a set of features (such as depicted in FIGS. 5A and 5B) of an SEM target with a pitch of 45 nm and a buried depth of 30 nm. The graph 900 shows a dashed line 914 corresponding to a set of features (such as depicted in FIGS. 5A and 5B) of an SEM target with a pitch of 60 nm and a buried depth of 30 nm. Each of the areas with sets of features (e.g., corresponding to the line 910, the dotted line 912, and the dashed line 914) may be contained within a single field of view (FOV) of an SEM image. A FOV may be the area for which an SEM system can acquire an image without significant drift. The FOV may contain features, areas, sets of features, etc. for which the SEM conditions may be assumed to be substantially similar. An SEM image for a single FOV may be acquired in a single operation (including raster scan) without stitching together of multiple images or significant resetting of SEM beam optics. For each of the sets of features of the SEM target, contrast exhibits a maximum at an optimal LE, where the optimal LE varies based on pitch. For the line 910, the optimal LE is approximately 22 keV; for the dotted line 912, the optimal LE is approximately 16 keV; and for the dashed line 914, the optimal LE is approximately 13 keV. The overall contrast is higher for larger pitches for all LEs depicted, but may exhibit cross over in some instances.

FIG. 6B depicts a graph 920 which depicts contrast (as a contrast to noise ratio along an axis 924) as a function of LE (in keV along an axis 922). The graph 920 shows a line 930 corresponding to a set of features (such as depicted in FIGS. 5A and 5B) of an SEM target with a pitch of 30 nm and a buried depth of 60 nm. The graph 920 shows a dotted line 932 corresponding to a set of features (such as depicted in FIGS. 5A and 5B) of an SEM target with a pitch of 45 nm and a buried depth of 60 nm. The graph 920 shows a dashed line 934 corresponding to a set of features (such as depicted in FIGS. 5A and 5B) of an SEM target with a pitch of 60 nm and a buried depth of 60 nm. Each of the areas with sets of features (e.g., corresponding to the line 930, the dotted line 932, and the dashed line 934) may be contained within a single FOV of an SEM image. For each of the sets of features of the SEM target, contrast exhibits a maximum at an optimal LE, where the optimal LE varies based on pitch. For the line 930, the optimal LE is approximately 30 keV; for the dotted line 932, the optimal LE is approximately 20 keV; and for the dashed line 934, the optimal LE is approximately 16 keV. For each pitch (e.g., pitch 30 nm of the line 930, pitch 45 nm of the dotted line 932, and pitch 60 nm of the dashed line 934), the optimal LE is greater for the buried depth of 60 nm of the graph 920 than for the buried depth of 30 nm of the graph 900 of FIG. 6A. The contrast for each pitch (e.g., pitch 30 nm of the line 930, pitch 45 nm of the dotted line 932, and pitch 60 nm of the dashed line 934) is smaller for the buried depth of 60 nm of the graph 920 than for the buried depth of 30 nm of the graph 900 of FIG. 6A The overall contrast is higher for larger pitches for all LEs depicted, but may exhibit cross over in some instances.

FIG. 6C depicts a graph 940 which depicts contrast (as a contrast to noise ratio along an axis 944) as a function of LE (in keV along an axis 942). The graph 940 shows a line 950 corresponding to set of features (such as depicted in FIGS. 5A and 5B) of an SEM target with a pitch of 30 nm and a buried depth of 120 nm. The graph 940 shows a dotted line 952 corresponding to a set of features (such as depicted in FIGS. 5A and 5B) of an SEM target with a pitch of 45 nm and a buried depth of 120 nm. The graph 940 shows a dashed line 954 corresponding to a set of features (such as depicted in FIGS. 5A and 5B) of an SEM target with a pitch of 60 nm and a buried depth of 120 nm. Each of the areas with sets of features (e.g., corresponding to the line 950, the dotted line 952, and the dashed line 954) may be contained within a single FOV of an SEM image. For each of the sets of features of the SEM target, contrast exhibits a maximum at an optimal LE over the depicted range of LE, where the optimal LE varies based on pitch. For the line 950, the optimal LE is approximately 50 keV (e.g., the maximum LE depicted); for the dotted line 952, the optimal LE is approximately 35 keV; and for the dashed line 954, the optimal LE is approximately 26 keV. For each pitch (e.g., pitch 30 nm of the line 950, pitch 45 nm of the dotted line 952, and pitch 60 nm of the dashed line 954), the optimal LE is greater for the buried depth of 120 nm of the graph 940 than for the buried depth of 60 nm of the graph 920 of FIG. 6B. The contrast for each pitch (e.g., pitch 30 nm of the line 950, pitch 45 nm of the dotted line 952, and pitch 60 nm of the dashed line 954) is smaller for the buried depth of 120 nm of the graph 940 than for the buried depth of 60 nm of the graph 920 of FIG. 6B. The overall contrast is higher for larger pitches for all LEs depicted, but may exhibit cross over in some instances.

A relationship between LE and contrast for measurable structural characteristic can be determined for a SEM system. Such a relationship may be determined by modeling. Such a relationship may be determined by taking baseline measurements of the SEM system. Such as relationship may be determined by a mixture of experimental and modeling means. A performance indicator for the SEM system can then be determined by comparing measured values of contrast for one or more LE to the relationship between LE and contrast for measurable structural characteristics. The performance indicator can be determined for different types of features. For example, the performance indicator can be determined for one-dimensional features, two-dimensional features, two-dimensional features in various orientations, etc. The performance indicator can be used to measure performance of an SEM alignment. The performance indicator may indicate beam spot size, beam alignment, LE accuracy, etc.

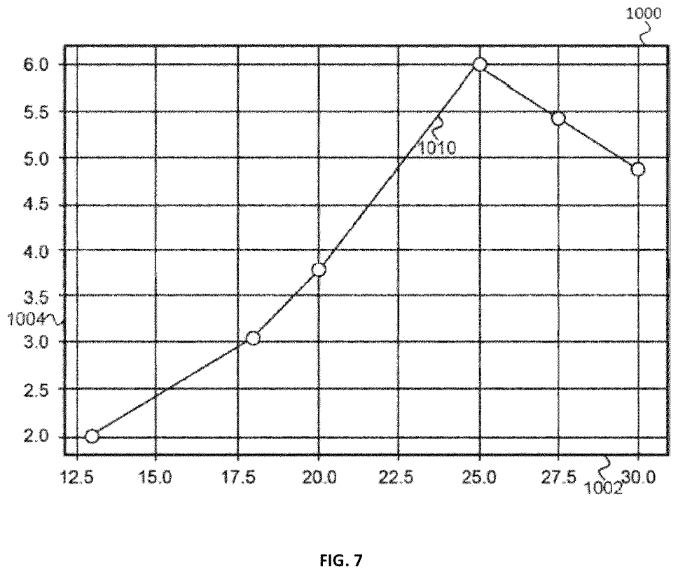

FIG. 7 depicts an example graph of a measured relationship between contrast and landing energy for a SEM target comprising buried features. FIG. 7 depicts a graph 1000 which depicts contrast (as a contrast to noise ratio along an axis 1004) as a function of LE (in keV along an axis 1002). The graph 1000 shows a line 1010 corresponding to a set of features (such as depicted in FIGS. 5A and 5B) of an SEM target. The contrast for the SEM target is measured at multiple LEs, such as at 13 keV, 18 keV, 20 keV, 25 keV, 27.5 keV, and 30 keV. For the measurement structure, contrast exhibits a maximum at an optimal LE over the depicted range of LE. For the line 1010, the optimal LE is approximately 25 keV. In some embodiments, a measured relationship may include measured relationships for sets of features with various measurable structural characteristics. The measured relationship may be determined based on selected LE, where each LE may correspond to an acquired SEM image from the SEM system. The measured relationship may be determined for multiple features, areas, sets of features, etc. of an SEM target contained within a single FOV of the SEM system.

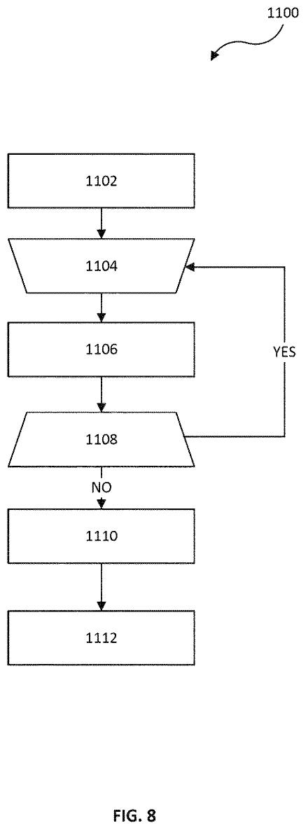

FIG. 8 illustrates a method of SEM evaluation based on a SEM target comprising buried features of various pitches. Each of these operations is described in detail below. The operations of method 1100 presented below are intended to be illustrative. In some embodiments, method 1100 may be accomplished with one or more additional operations not described, and/or without one or more of the operations discussed. Additionally, the order in which the operations of method 1100 are illustrated in FIG. 8 and described below is not intended to be limiting. In some embodiments, one or more portions of method 1100 may be implemented (e.g., by simulation, modeling, etc.) in one or more processing devices (e.g., one or more processors). The one or more processing devices may include one or more devices executing some or all of the operations of method 1100 in response to instructions stored electronically on an electronic storage medium. The one or more processing devices may include one or more devices configured through hardware, firmware, and/or software to be specifically designed for execution of one or more of the operations of method 1100, for example.

At an operation 1102, an SEM image is acquired. The SEM image may correspond to multiple features, sets of features, areas, etc. The SEM image may correspond to a single FOV. The SEM image may be of the entirety or a portion of the SEM target. The SEM image is acquired at a given LE, which value is acquired along with the SEM image.

At an operation 1104, an area of the SEM image is identified which corresponds to a given pitch. The area of the SEM image may be selected based on location in the SEM image (e.g., from left to right, from center outwards), based on pitch (e.g., from smallest pitch to largest pitch, etc.). Pitch may instead be another one or more of measurable structural characteristics. The area of the SEM image corresponding to the pitch may be an area (such as areas 724 of the FIG. 4), a set of features (such as the features 852 of FIG. 5B), etc. The area of the SEM image is identified along with its pitch, where the pitch may be known based on fabrication parameters (e.g., design layout) or which may be measured based on the SEM image. The areas of the SEM image which correspond to pitches may comprise some or all of the SEM image. The SEM image may contain areas which do not correspond to a pitch or other feature for contrast and/or resolution determination.

At an operation 1106, a contrast and/or resolution is determined for the area of the SEM image corresponding to the given pitch. The contrast and/or resolution may be determined based on pixel values of the SEM image. The contrast and/or resolution may be determined as an absolute value, a relative value, etc. The contrast and/or resolution may be determined as a ratio, a derivative, etc.

At an operation 1108, it is determined if other areas of the SEM image (which correspond to a pitch) remain to be identified. It may instead be determined that other pitches remain for identification. If other areas of the SEM image remain to be identified, flow continues to the operation 1106, where another area of the SEM image is identified. If other areas of the SEM image do not remain to be identified, flow continues to an operation 1110, where an SEM performance indicator is determined.

At an operation 1110, a performance indicator is determined based on the determined contrast and/or resolution of the areas of the SEM image. The performance indicator may be qualitative (e.g., SEM alignment is good), may be relative (e.g., SEM alignment is better than previously determined), may be quantitative (e.g., SEM alignment is 90% of optimal alignment), etc. The performance indicator may be determined for multiple pitches. The performance indicator may instead be determined based on multiple pitches.

At an operation 1112, the SEM system may be adjusted based on the performance indicator. The SEM system may be further aligned based on a performance indicator which indicates alignment is less than optimal. The SEM system may not be further aligned, such as based on a performance indicator which indicates that alignment exceeds a threshold. The SEM system may be adjusted in other ways, such as by having LE adjusted, which are not alignment operations.

As described above, method 1100 (and/or the other methods and systems described herein) is configured SEM evaluation based on a SEM target comprising buried features of various pitches.

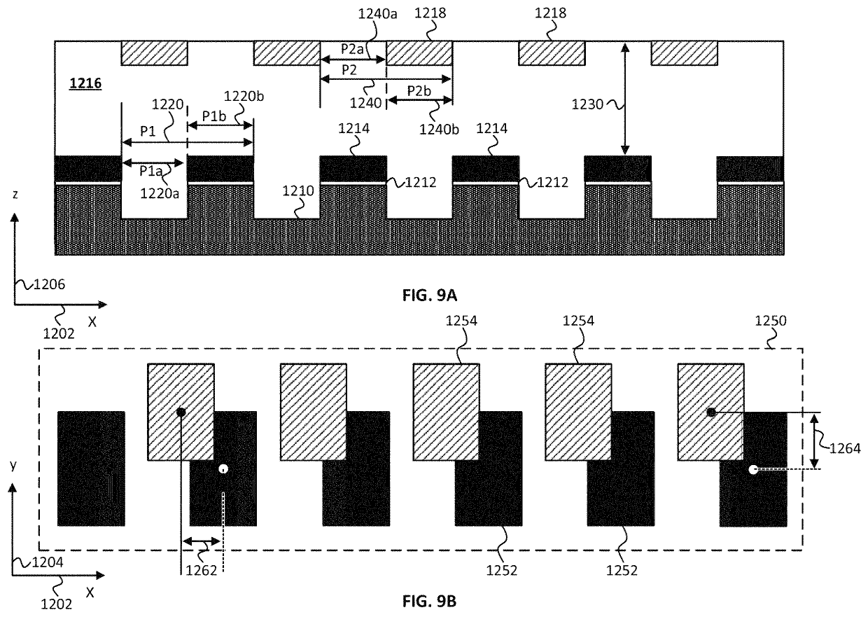

FIGS. 9A-9B depict views of overlay features in an example SEM target. FIG. 9A depicts a cross-sectional view of a portion of the example SEM target, depicted with respect to a z-axis 1206 and an x-axis 1202. As with other generic axis described herein, the generic axes are provided for ease of description. The example SEM target may comprise a substrate 1210 (which may instead be a bottom layer, bulk layer, etc., such as silicon-on-insulator), a buried feature layer 1214, a fill layer 1216, and a top feature layer 1218. Interfaces between layers may comprise one or more adhesion or interstitial layer, such as adhesion layer 1212 depicted between the substrate 1210 and the buried feature layer 1214.

The substrate 1210 may be etched or otherwise patterned, such as during a process which creates features in the buried feature layer 1214 and/or creates features in the top feature layer 1218. In some embodiments, the substrate 1210 may be unpatterned. The buried feature layer 1214 may comprise features (e.g., one-dimensional features, two-dimensional features, etc.) with measurable structural characteristics. The buried feature layer 1214 may comprise features with a pitch 1220, where the pitch 1220 is depicted along the x-axis 1202 for ease of description. The pitch 1220 may be symmetric, where features of the buried feature layer 1214 may have a substantially similar feature size 1220b and feature separation 1220a. In some embodiments, the pitch 1220 may be asymmetric, where the features of the buried feature layer 1214 may have a feature size 1220b and feature separation 1220a which differ. The buried feature layer 1214 may be located at a buried depth 1230.

The top feature layer 1218 may comprise features (e.g., one-dimensional features, two-dimensional features, etc.) with measurable structural characteristics. The features of the top feature layer 1218 may comprise features with the same or different measurable structural characteristics of the buried feature layer 1214. The top feature layer 1218 may comprise features with a pitch 1240, where the pitch 1240 is depicted along the x-axis 1202 for ease of description. The pitch 1240 may be symmetric, where features of the top feature layer 1218 may have a substantially similar feature size 1240b and feature separation 1240a. In some embodiments, the pitch 1240 may be asymmetric, where the features of the top feature layer 1218 may have a feature size 1240b and feature separation 1240a which differ. The pitch 1240 may be the same or different than the pitch 1220. FIG. 9A (and FIG. 9B) as depicted illustrate an example in which pitch 1240 is equal to pitch 1220. The feature size 1240b may be the same as or different than the feature size 1220b. The feature separation 1240a may be the same as or different than the feature separation 1220a. Within an area, the pitch 1220 and the pitch 1240 may be substantially equal (which the feature separation 1240a and the feature separation 1240a as well as the feature size 1220b and the feature size 1220b may be different), such that the buried feature layer 1214 and the top feature layer 1218 have substantially the same lateral offset (as depicted in x-direction) within the area.

The buried depth 1230 may correspond to depth, such as a depth of electron penetration, for an SEM. The buried depth 1230 may be determined based on a corresponding depth of a feature of a production wafer. The buried depth 1230 may be selected based on a landing energy (LE) for an SEM, such as a LE for imaging of production wafers, where depth of electron penetration is a function of LE. The buried depth 1230 may include a depth of the top feature layer 1218 (e.g., from the surface of the SEM target as depicted) or may measure the distance between a top of the buried feature layer 1214 and a bottom of the top feature layer 1218. In some embodiments, an additional top or cap layer may be fabricated on top of the top feature layer 1218, where the depth of additional layer(s) may or may not be included in a determination of the buried depth 1230. The substrate 1210 may be grounded, including via a backside electrode or metal layer, or otherwise provided with a source of electrons.

The materials which comprise the substrate 1210, the buried feature layer 1214, the fill layer 1216, and the top feature layer 1218 may have different SEM characteristics. For example, the substrate 1210, the buried feature layer 1214, and the top feature layer 1218 may have contrasting SEM imaging characteristics, such as backscattering coefficient n, secondary electron yield ô, etc. The substrate 1210, the buried feature layer 1214, and the top feature layer 1218 may have contrasting brightness, such as due to contrasting material type or conductivity (e.g., metal versus semiconductor), atomic number (e.g., titanium versus silicon), etc.

FIG. 9B depicts a substrate-plane view of an example SEM target (e.g., as depicted in FIG. 9A), depicted with respect to the x-axis 1202 and a y-axis 1204. As with other generic axis described herein, the generic axes are provided for ease of description. A dashed rectangle 1250 encloses buried features 1252 and top features 1254 of at least a portion of the example SEM target. The dashed rectangle 1250 may enclose an area corresponding to an area of SEM target, such as the areas 724 of FIG. 4. The dashed rectangle 1250 is depicted as a polygon pattern

The buried features 1252 may correspond to features of the buried feature layer (e.g., the buried feature layer 1214 of FIG. 9A). The top features 1254 may correspond to features of the top feature layer (e.g., the top feature layer 1218 of FIG. 9A). The buried features 1252 and the top features 1254 are depicted as rectangles, but may comprise other features, such as contact holes, lines, irregular features, etc. The buried features 1252 and the top features 1254 may be features of the same or different shape. The buried features 1252 and the top features 1254 may be features of the same or different size in one or more dimension. The buried features 1252 and the top features 1254 may be offset in one or more lateral direction (e.g., along the x-axis 1202, along the y-axis 1204, etc.). The buried features 1252 and the top features 1254 may be offset by a first lateral offset 1262, depicted along the x-axis 1202. The buried features 1252 and the top features 1254 may be offset by a second lateral offset 1264, depicted along the y-axis 1204. The buried features 1252 and the top features 1254 may have negligible lateral offsets—e.g., the first lateral offset 1262 and the second lateral offset 1264 may be substantially zero. As sizes and shapes of the buried features 1252 and the top features 1254 may be different, the buried features 1252 and the top features 1254 may incompletely overlay even if the first lateral offset 1262 and the second lateral offset 1264 are substantially zero. The buried features 1252 and the top features 1254 may be partially overlapping, for example when the first lateral offset 1262 and the second lateral offset 1264 are smaller than half the size of the smallest of the buried features 1252 and the top features 1254. The buried features 1252 and the top features may be non-overlapping, for example when the first lateral offset 1262 and the second lateral offset 1264 are larger than the size of the largest of the buried features 1252 and the top features 1254.

The dashed rectangle 1250 may correspond to an SEM image of at least a portion of the example SEM target. The SEM image may contain areas (e.g., regions of pixels) which correspond to signals from the buried features 1252. The SEM image may contain areas (e.g., regions of pixels) which correspond to signals from the top features 1254. The SEM image may contain areas which contain signals which correspond to other layers of the example SEM target (e.g., the fill layer 1216, the adhesion layer 1212, etc.) which may be patterned or unpatterned. A measure of overlay may be determined based on the SEM image. The measure of overlay may be determined based on template matching or other image processing methods. The measure of overlay may measure characteristics of the SEM image corresponding to at least one of the first lateral offset 1262, the second lateral offset 1264 or a combination thereof. The measure of overlay may depend on contrast, for example because template matching accuracy may depend on contrast levels determination of a measure of overlay may depend on contrast levels.

A measure of overlay precision may be determined based on the measure of overlay and knowledge of at least one of the first lateral offset 1262, the second lateral offset 1264, or a combination thereof. The first lateral offset 1262 may be known based on fabrication details, such as a design layout. The second lateral offset 1264 may be known based on fabrication details, such as a design layout. A measure of overlay precision may be determined may on a signal to noise ratio (SNR) of intensity level of various areas of the SEM image. The measure of overlay precision may be determined based on a distribution of the measure of overlay over repeatable unit cells (including all repeatable unit cells, substantially all repeatable unit cells, some repeatable unit cells, etc.). The repeatable unit cell may comprise one or more buried feature 1252 and top feature 1254. The measure of overlay precision may be determined based on a standard deviation of the measure of overlay over multiple repeatable unit cells. The measure of overlay precision may be determined as an absolute value (e.g., in nm), as a percentage, etc. A measure of overlay precision may be determined for multiple measurable structural characteristics, for example corresponding to pitch in multiple areas (such as the areas 724 of FIG. 4).

The measure of overlay precision may be determined for multiple features, sets of features, areas, etc. of the SEM target, where at least some of the sets of features have different measurable structural characteristics. In some cases, a measure of overlay precision may not be determined for one or more sets of features of the SEM target, such as if the SEM image is not clear enough to differentiate buried features and top features. The measure of overlay precision may be a function of measurable structural characteristics, such as pitch, buried depth, feature size, etc. The contrast may be a function of SEM parameters, such as LE, beam spot size, detector type, etc.

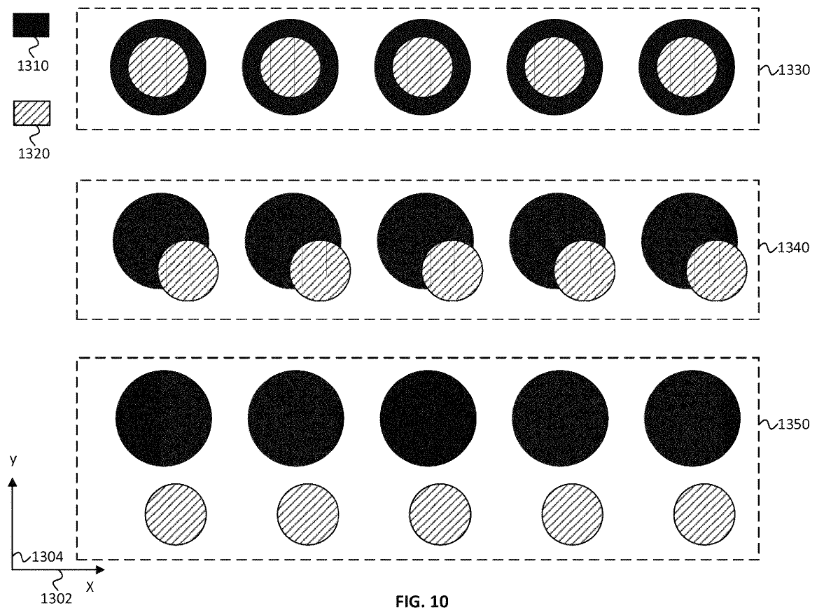

FIG. 10 depicts example overlay relationships in an example SEM target. FIG. 10 depicts a substrate-plane view of areas of at least a portion of the example SEM target, depicted with respect to an x-axis 1302 and a y-axis 1304. As with other generic axis described herein, the generic axes are provided for ease of description. FIG. 10 depicts areas 1330, 1340, and 1350 which comprise areas of the example SEM target (e.g., such as areas 724 of FIG. 4). The areas 1330, 1340, and 1350 contain buried features 1310 and top features 1320. The buried features 1310 of the area 1330 are coaxial with the top features 1320 of the area 1330. The buried features 1310 of the area 1340 are laterally offset in both the x-direction and the y-direction with respect to the top features of the area 1340. The buried features 1310 and the top features 1320 of the area 1330 are partially overlapping. The buried features 1310 of the area 1350 are laterally offset in both the x-direction and the y-direction with respect to the top features of the area 1350, where the offset in the y-direction is greater than the offset in the x-direction. The buried features 1310 and the top features 1320 of the area 1350 are non-overlapping. An example SEM target may comprise areas with various features with varying measurable structural characteristics, such as the areas 1330, 1340, and 1350. The areas 1330, 1340, and 1350 are provided as illustrative examples, where areas of a SEM target may vary in feature size, feature shape, one or more lateral offset, etc.

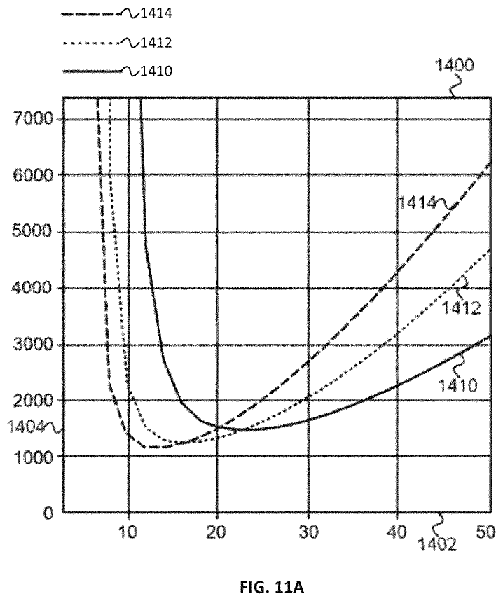

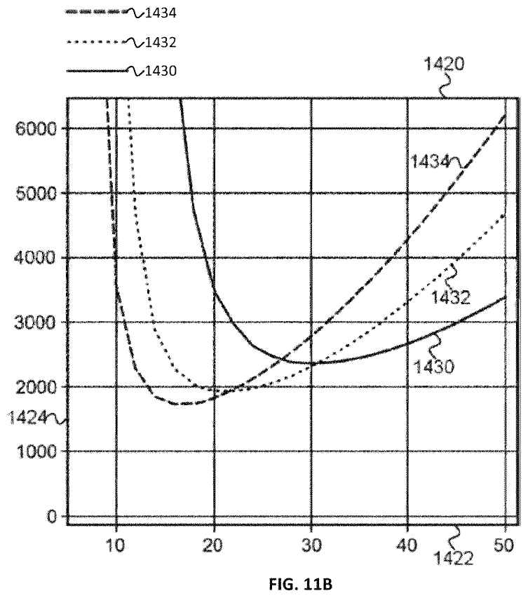

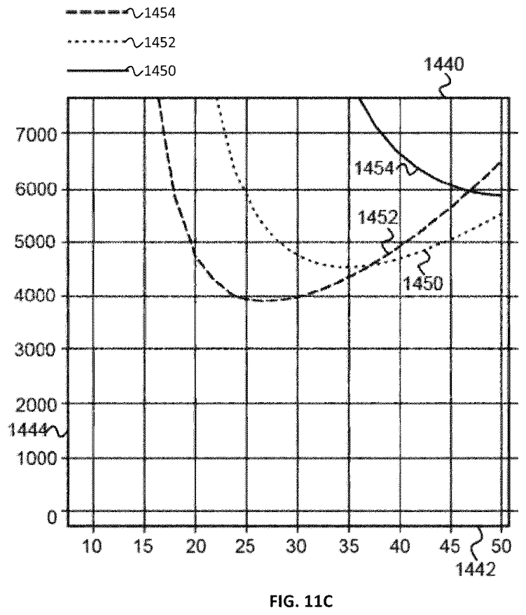

FIGS. 11A-11C depict example graphs of a relationship between precision and landing energy for a SEM target comprising overlay features, according to an embodiment. FIG. 11A depicts a graph 1400 which depicts overlay precision (along an axis 1404) as a function of LE (in keV along an axis 1402). The graph 1400 shows a line 1410 corresponding to a set of features (such as depicted in FIGS. 9A and 9B) of an SEM target with a pitch of 30 nm and a buried depth of 30 nm. The graph 1400 shows a dotted line 1412 corresponding to a set of features (such as depicted in FIGS. 9A and 9B) of an SEM target with a pitch of 45 nm and a buried depth of 30 nm. The graph 1400 shows a dashed line 1414 corresponding to a set of features (such as depicted in FIGS. 9A and 9B) of an SEM target with a pitch of 60 nm and a buried depth of 30 nm. Each of the sets of features (e.g., corresponding to the line 1410, the dotted line 1412, and the dashed line 1414) may be contained within a single FOV of an SEM image. For each of the areas of the SEM target, overlay precision exhibits a minimum at a minimal LE, where the minimal LE varies based on pitch. For the line 1410, the minimal LE is approximately 24 keV; for the dotted line 1412, the minimal LE is approximately 15 keV; and for the dashed line 1414, the minimal LE is approximately 12 keV. The overlay precision is a function of both pitch and LE, where overlay precision is greater for larger pitches at higher LEs and lower for larger pitches at low LEs.

FIG. 11B depicts a graph 1420 which depicts overlay precision (along an axis 924) as a function of LE (in keV along an axis 1422). The graph 1420 shows a line 1430 corresponding to a set of features (such as depicted in FIGS. 9A and 9B) of an SEM target with a pitch of 30 nm and a buried depth of 60 nm. The graph 1420 shows a dotted line 1432 corresponding to a set of features (such as depicted in FIGS. 9A and 9B) of an SEM target with a pitch of 45 nm and a buried depth of 60 nm. The graph 1420 shows a dashed line 1434 corresponding to a set of features (such as depicted in FIGS. 9A and 9B) of an SEM target with a pitch of 60 nm and a buried depth of 60 nm. Each of the sets of features (e.g., corresponding to the line 1430, the dotted line 1432, and the dashed line 1434) may be contained within a single FOV of an SEM image. For each of the features, areas, sets of features, etc. of the SEM target, contrast exhibits a minimum at a minimal LE, where the minimal LE varies based on pitch. For the line 1430, the minimal LE is approximately 30 keV; for the dotted line 1432, the minimal LE is approximately 22 keV; and for the dashed line 1434, the minimal LE is approximately 16 keV. The overlay precision is a function of both pitch and LE, where overlay precision is greater for larger pitches at higher LEs and lower for larger pitches at low LEs. The points at which the lines interest (e.g., where the line 1430 meets the dotted line 1432, where the line 1430 meets the dashed line 1434, and where the dotted line 1432 meets the dashed line 1434) occur at greater LEs for the graph 1420 than for the graph 1400 of FIG. 11A.

FIG. 11C depicts a graph 1440 which depicts overlay precision (along an axis 944) as a function of LE (in keV along an axis 1442). The graph 1440 shows a line 1450 corresponding to a set of features (such as depicted in FIGS. 9A and 9B) of an SEM target with a pitch of 30 nm and a buried depth of 120 nm. The graph 1440 shows a dotted line 1452 corresponding to a set of features (such as depicted in FIGS. 9A and 9B) of an SEM target with a pitch of 45 nm and a buried depth of 120 nm. The graph 1440 shows a dashed line 1454 corresponding to a set of features (such as depicted in FIGS. 9A and 9B) of an SEM target with a pitch of 60 nm and a buried depth of 120 nm. Each of the sets of features (e.g., corresponding to the line 1450, the dotted line 1452, and the dashed line 1454) may be contained within a single FOV of an SEM image of the SEM target. For each of the sets of features, overlay precision exhibits a minimum at a minimal LE over the depicted range of LE, where the minimal LE varies based on pitch. For the line 1450, the minimal LE is approximately 50 keV (e.g., the maximum LE depicted); for the dotted line 1452, the minimal LE is approximately 35 keV; and for the dashed line 1454, the minimal LE is approximately 26 keV. Contrast and precision may be inversely related. The points at which the lines interest (e.g., where the line 1430 meets the dotted line 1432, where the line 1430 meets the dashed line 1434, and where the dotted line 1432 meets the dashed line 1434) occur at greater LEs for the graph 1440 than for the graph 1420 of FIG. 11B.

A relationship between LE and overlay precision for measurable structural characteristic can be determined for a SEM system. Such a relationship may be determined by modeling. Such a relationship may be determined by taking baseline measurements of the SEM system. Such as relationship may be determined by a mixture of experimental and modeling means. A performance indicator for the SEM system can then be determined by comparing measured values of overlay precision for one or more LE to the relationship between LE and overlay precision for measurable structural characteristics. The performance indicator can be determined for different types of features. For example, the performance indicator can be determined for one-dimensional features, two-dimensional features, two-dimensional features in various orientations, etc. The performance indicator can be used to measure performance of an SEM alignment. The performance indicator may indicate beam spot size, beam alignment, LE accuracy, etc.

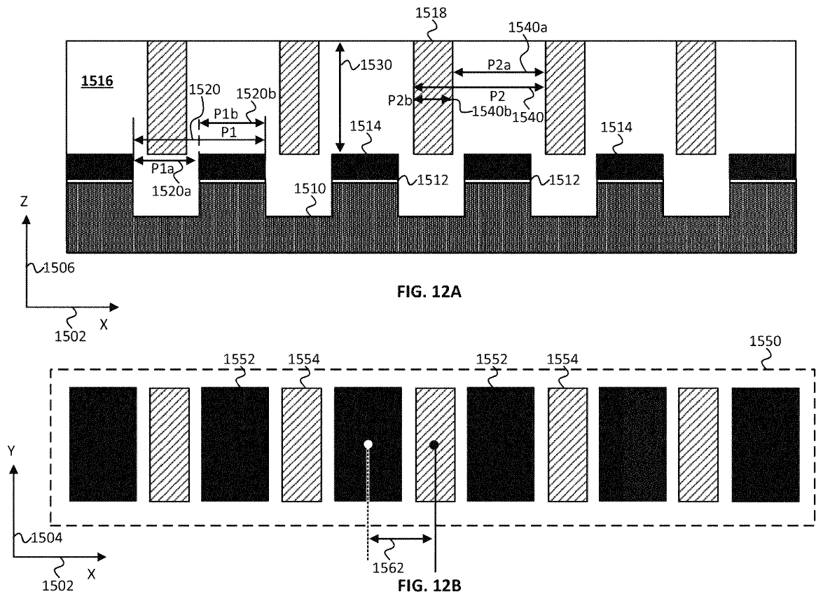

FIGS. 12A-12B depict views of tilt angle calibration features in an example SEM target. FIG. 12A depicts a cross-sectional view of at least a portion of the example SEM target, depicted with respect to a z-axis 1506 and an x-axis 1502. As with other generic axis described herein, the generic axes are provided for ease of description. The example SEM target may comprise a substrate 1510 (which may instead be a bottom layer, bulk layer, etc., such as silicon-on-insulator), a buried feature layer 1514, a fill layer 1516, and a top feature layer 1518. Interfaces between layers may comprise one or more adhesion or interstitial layer, such as adhesion layer 1512 depicted between the substrate 1510 and the buried feature layer 1514.

The substrate 1510 may be etched or otherwise patterned, such as during a process which creates features in the buried feature layer 1514 and/or creates features in the top feature layer 1518. In some embodiments, the substrate 1510 may be unpatterned. The buried feature layer 1514 may comprise features (e.g., one-dimensional features, two-dimensional features, etc.) with measurable structural characteristics. The buried feature layer 1514 may comprise features with a pitch 1520, where the pitch 1520 is depicted along the x-axis 1502 for ease of description. The pitch 1520 may be symmetric, where features of the buried feature layer 1514 may have a substantially similar feature size 1520b and feature separation 1520a. In some embodiments, the pitch 1520 may be asymmetric, where the features of the buried feature layer 1514 may have a feature size 1520b and feature separation 1520a which differ. The buried feature layer 1514 may be located at a buried depth 1530.

The top feature layer 1518 may comprise features (e.g., one-dimensional features, two-dimensional features, etc.) with measurable structural characteristics. The features of the top feature layer 1518 may comprise features with the same or different measurable structural characteristics of the buried feature layer 1514. The top feature layer 1518 may comprise features with a pitch 1540, where the pitch 1540 is depicted along the x-axis 1502 for ease of description. The pitch 1540 may be symmetric, where features of the top feature layer 1518 may have a substantially similar feature size 1540b and feature separation 1540a. In some embodiments, the pitch 1540 may be asymmetric, where the features of the top feature layer 1518 may have a feature size 1540b and feature separation 1540a which differ. The pitch 1540 may be the same or different than the pitch 1520. The feature size 1540b may be the same as or different than the feature size 1520b. The feature separation 1540a may be the same as or different than the feature separation 1520a. Within an area, the pitch 1520 and the pitch 1540 may be substantially equal (which the feature separation 1540a and the feature separation 1520a as well as the feature size 1520b and the feature size 1520b may be different), such that the buried feature layer 1514 and the top feature layer 1518 have substantially the same lateral offset (as depicted in x-direction) within the area.

The buried depth 1530 may correspond to depth, such as a depth of electron penetration, for an SEM. The buried depth 1530 may be selected based on a corresponding depth of a feature of a production wafer. The buried depth 1530 may be selected based on a landing energy (LE) for an SEM, such as a LE for imaging of production wafers, where depth of electron penetration is a function of LE. The buried depth 1530 may include a depth of the top feature layer 1518 (e.g., from the surface of the SEM target as depicted) or may measure the distance between a top of the buried feature layer 1514 and a bottom of the top feature layer 1518. In some embodiments, an additional top or cap layer may be fabricated on top of the top feature layer 1518, where the depth of additional layer(s) may or may not be included in a determination of the buried depth 1530. In some embodiments, the top feature layer 1518 may be a layer is produced by filling an etched recess. The top feature layer 1518 may then be planarized, such as via chemical mechanical polishing, to be substantially even with the surface of the fill layer 1516. The substrate 1510 may be grounded, including via a backside electrode or metal layer, or otherwise provided with a source of electrons.

The materials which comprise the substrate 1510, the buried feature layer 1514, the fill layer 1516, and the top feature layer 1518 may have different SEM characteristics. For example, the substrate 1510, the buried feature layer 1514, and the top feature layer 1518 may have contrasting SEM imaging characteristics, such as backscattering coefficient n, secondary electron yield 8, etc. The substrate 1510, the buried feature layer 1514, and the top feature layer 1518 may have contrasting brightness, such as due to contrasting material type or conductivity (e.g., metal versus semiconductor), atomic number (e.g., titanium versus silicon), etc.

FIG. 12B depicts a substrate-plane view of tilt angle calibration features in an example SEM target (e.g., as depicted in FIG. 12A), depicted with respect to the x-axis 1502 and a y-axis 1504. As with other generic axis described herein, the generic axes are provided for ease of description. A dashed rectangle 1550 encloses buried features 1552 and top features 1554 of the example SEM target. The dashed rectangle 1550 may enclose an area corresponding to an area of SEM target, such as the areas 724 of FIG. 4. The dashed rectangle 1550 is depicted as a polygon pattern

The buried features 1552 may correspond to features of the buried feature layer (e.g., the buried feature layer 1514 of FIG. 12A). The top features 1554 may correspond to features of the top feature layer (e.g., the top feature layer 1518 of FIG. 12A). The buried features 1552 and the top features 1554 are depicted as rectangles, but may comprise other features, such as contact holes, lines, irregular features, etc. The buried features 1552 and the top features 1554 may be features of the same or different shape. The buried features 1552 and the top features 1554 may be features of the same or different size in one or more dimension. The buried features 1552 and the top features 1554 may be offset in one or more lateral direction (e.g., along the x-axis 1502, along the y-axis 1504, etc.).

The buried features 1552 and the top features 1554 may be offset by a first lateral offset 1562, depicted along the x-axis 1502. The buried features 1552 and the top features 1554 may also or instead be offset by a second lateral offset, along the y-axis 1504. In the illustrative example, a negligible second lateral offset is depicted. The buried features 1552 and the top features 1554 may have negligible lateral offsets—e.g., the first lateral offset 1562 and the second lateral offset may be substantially zero. As sizes and shapes of the buried features 1552 and the top features 1554 may be different, the buried features 1552 and the top features 1554 may incompletely overlay even if the first lateral offset 1562 and the second lateral offset are substantially zero. The buried features 1552 and the top features 1554 may be partially overlapping, for example when the first lateral offset 1562 and the second lateral offset are smaller than half the size of the smallest of the buried features 1552 and the top features 1554. The buried features 1552 and the top features may be non-overlapping, for example when the first lateral offset 1562 and the second lateral offset are larger than the size of the largest of the buried features 1552 and the top features 1554.

The dashed rectangle 1550 may correspond to an SEM image of the example SEM target. The SEM image may contain areas (e.g., regions of pixels) which correspond to signals from the buried features 1552. The SEM image may contain areas (e.g., regions of pixels) which correspond to signals from the top features 1554. The SEM image may contain areas which contain signals which correspond to other layers of the example SEM target (e.g., the fill layer 1516, the adhesion layer 1512, etc.) which may be patterned or unpatterned. A measure of overlay may be determined based on the SEM image. The measure of overlay may be determined based on template matching or other image processing methods. The measure of overlay may measure characteristics of the SEM image corresponding to at least one of the first lateral offset 1562, the second lateral offset, or a combination thereof. The measure of overlay may depend on contrast, for example because template matching accuracy may depend on contrast levels determination of a measure of overlay may depend on contrast levels.

A set-get overlay relationship may be determined based on the measure of overlay and knowledge of the first lateral offset 1562 and the second lateral offset. The first lateral offset 1562 may be known based on fabrication details, such as a design layout. The second lateral offset may be known based on fabrication details, such as a design layout. The set-get overlay relationship may be determined based on multiple measurements of overlay for SEM images with different lateral offsets.

For each lateral direction, the set-get overlay relationship may be determined based on a fitted first order polynomial function. The set-get overlay relationship may be plotted (for example as a scatter plot) for multiple values of known overlay (e.g., set overlay) and multiple measured values of overlay (e.g., get overlay). A slope and/or offset may be determined for the set-get overlay relationship for a given set of features (e.g., the set of features of FIGS. 12A and 12B with varying lateral offsets) of an SEM target. Multiple set-get overlay relationships may be determined for multiple measurable structural characteristics, for example corresponding to pitch in multiple areas (such as the areas 724 of FIG. 4).

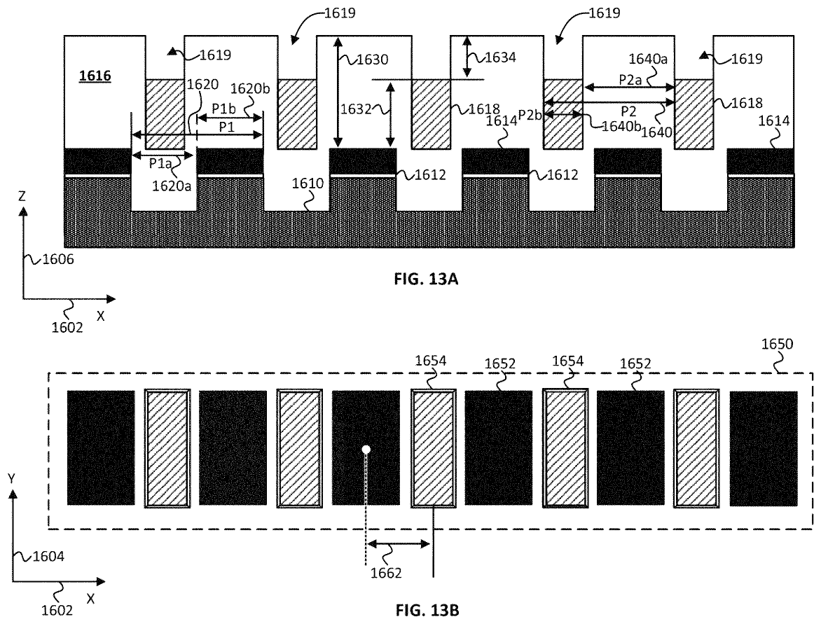

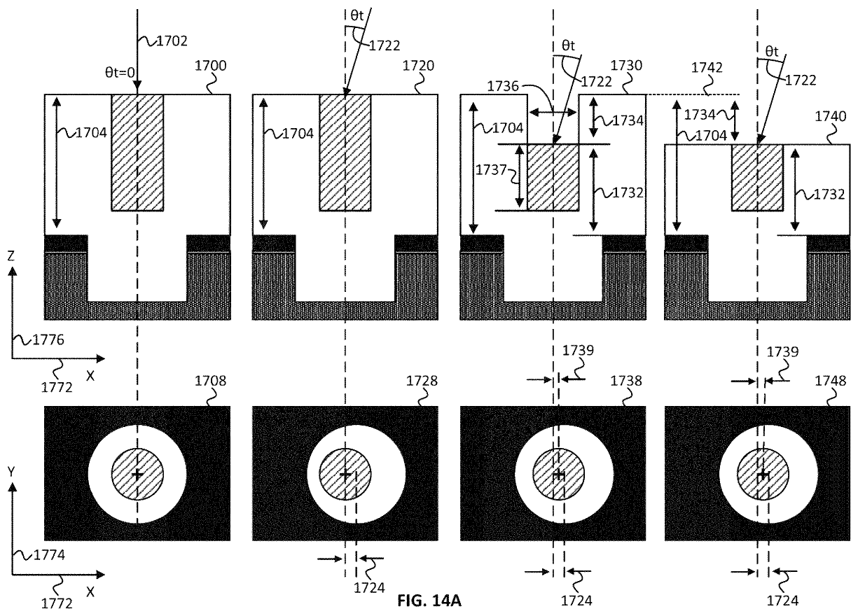

FIGS. 13A-13B depict views of tilt angle calibration features with recesses in an example SEM target. FIGS. 13A and 13B correspond to features which are similar to the structure depicted in FIGS. 12A and 12B except that the top features of FIGS. 13A and 13B are recessed. FIG. 13A depicts a cross-sectional view of at least a portion of the example SEM target, depicted with respect to a z-axis 1606 and an x-axis 1602. As with other generic axis described herein, the generic axes are provided for ease of description. The example SEM target may comprise a substrate 1610 (which may instead be a bottom layer, bulk layer, etc., such as silicon-on-insulator), a buried feature layer 1614, a fill layer 1616, a recessed top feature layer 1618, and recess layer 1619. Interfaces between layers may comprise one or more adhesion or interstitial layer, such as adhesion layer 1612 depicted between the substrate 1610 and the buried feature layer 1614.

The substrate 1610 may be etched or otherwise patterned, such as during a process which creates features in the buried feature layer 1614, creates features in the recessed top feature layer 1618, and/or creates features in the recess layer 1619. In some embodiments, the substrate 1610 may be unpatterned. The buried feature layer 1614 may comprise features (e.g., one-dimensional features, two-dimensional features, etc.) with measurable structural characteristics. The buried feature layer 1614 may comprise features with a pitch 1620, where the pitch 1620 is depicted along the x-axis 1602 for ease of description. The pitch 1620 may be symmetric, where features of the buried feature layer 1614 may have a substantially similar feature size 1620b and feature separation 1620a. In some embodiments, the pitch 1620 may be asymmetric, where the features of the buried feature layer 1614 may have a feature size 1620b and feature separation 1620a which differ. The buried feature layer 1614 may be located at a buried depth 1630.

The recessed top feature layer 1618 may comprise features (e.g., one-dimensional features, two-dimensional features, etc.) with measurable structural characteristics. The features of the recessed top feature layer 1618 may comprise features with the same or different measurable structural characteristics of the buried feature layer 1614. The recessed top feature layer 1618 may comprise features with a pitch 1640, where the pitch 1640 is depicted along the x-axis 1602 for ease of description. The pitch 1640 may be symmetric, where features of the recessed top feature layer 1618 may have a substantially similar feature size 1640b and feature separation 1640a. In some embodiments, the pitch 1640 may be asymmetric, where the features of the recessed top feature layer 1618 may have a feature size 1640b and feature separation 1640a which differ. The pitch 1640 may be the same or different than the pitch 1620. The feature size 1640b may be the same as or different than the feature size 1620b. The feature separation 1640a may be the same as or different than the feature separation 1620a. Within an area, the pitch 1620 and the pitch 1640 may be substantially equal (which the feature separation 1620a and the feature separation 1640a as well as the feature size 1620b and the feature size 1640b may be different), such that the buried feature layer 1614 and the recessed top feature layer 1618 have substantially the same lateral offset (as depicted in x-direction) within the area.

The recessed top feature layer 1618 may be recessed by a recess depth 1634, corresponding to the recess layer 1619. The recess layer 1619 may correspond to a void space. The recess layer 1619 may be created by etching, such as by selective etching of the recessed top feature layer 1618. The recessed top feature layer 1618 may have a fill depth 1632. The fill depth 1632 may be created by filling a void feature to generate the recessed top feature layer 1618, where the recessed top feature layer 1618 may be subsequently etched to generate the recess layer 1619. The recess layer 1619 may be created by etching of the recessed top feature layer 1618. The buried depth 1630 may or may not correspond substantially to the sum of the recess depth 1634 and the fill depth 1632. The recess layer 1619 may constitute a substantial portion of the buried depth 1630. For example, the recess depth 1634 may be more than half of the buried depth 1630. The set of features of FIGS. 12A and 12B may be substantially similar to the set of features of FIGS. 13A and 13B, except for the presence of the recess layer 1619 with the recess depth 1634 in FIG. 13A.

The buried depth 1630 may correspond to depth, such as a depth of electron penetration, for an SEM. The buried depth 1630 may be the same as a buried depth for a set of features with a negligible recess depth 1634.

In some embodiments, tilt angle calibration features with substantially similar buried depths but different recessed depths may be located adjacent to one another. In some embodiments, tilt angle calibration features with substantially similar buried depths but different recessed depths may be located in areas which are substantially adjacent, including in interspersed areas. Tilt angle calibration features with substantially similar buried depths but different recessed depths may include features with relationships such as those depicted in FIGS. 12A-12B and FIGS. 13A-13B. Tilt angle calibration features with substantially similar buried depths but different recessed depths may be substantially similar where the only substantial difference between features may be recessed top features (e.g., presence of a recess layer). Different recess depths may allow different set-get relationships (e.g., corresponding to the different recess depths) to be determined, where beam tilt angle may be determined based on the different set-get relationships. Larger recess depths may be more sensitive to beam tilt angle and therefore allow for higher beam tilt angle determination sensitivity.

The buried depth 1630 may be selected based on a corresponding depth of a feature of a production wafer. For SEM beam tilt angle calibration, the buried depth 1630 may be selected based on a depth corresponding to a landing energy (LE) for an SEM, where depth of electron penetration may vary based on LE. The buried depth 1630 may include a depth of the recessed top feature layer 1618 (e.g., as depicted) or may measure the distance between a top of the buried feature layer 1614 and a bottom of the recessed top feature layer 1618. In some embodiments, an additional top or cap layer may be fabricated on top of the recessed top feature layer 1618, where the depth of additional layer(s) may or may not be included in a determination of the buried depth 1630. Additional layers may be formed on top of the fill layer 1616 and not on top of the recesses above the features of the recessed top feature layer 1618. The buried depth 1630 may be substantially the same as the buried depth 1530 of FIG. 12A.

The materials which comprise the substrate 1610, the buried feature layer 1614, the fill layer 1616, and the recessed top feature layer 1618 may be substantially the same as the materials which comprise the substrate 1510, the buried feature layer 1514, the fill layer 1516, and the top feature layer 1518 of FIG. 12A. The recess layer 1619 may be a void layer or may be a fill layer, where the recess layer 1619 may be relatively transparent to SEM imaging.

FIG. 13B depicts a substrate-plane view of tilt angle calibration features in an example SEM target (e.g., as depicted in FIG. 13A), depicted with respect to the x-axis 1602 and a y-axis 1604. As with other generic axis described herein, the generic axes are provided for ease of description. A dashed rectangle 1650 encloses buried features 1652 and top features 1654 of the example SEM target. The dashed rectangle 1650 may enclose an area corresponding to an area of SEM target, such as the areas 724 of FIG. 4. The dashed rectangle 1650 is depicted with asymmetrical dimensions (e.g., with a long axis along the x-axis 1602 and with a short axis along the y-axis 1604), but the example SEM target may comprise areas with or without symmetrical dimensions.

The buried features 1652 may correspond to features of the buried feature layer (e.g., the buried feature layer 1614 of FIG. 13A). The top features 1654 may correspond to features of the top feature layer (e.g., the recessed top feature layer 1618 of FIG. 13A). The buried features 1652 and the top features 1654 are depicted as rectangles, but may comprise other features, such as contact holes, lines, irregular features, etc. The buried features 1652 and the top features 1654 may be features of the same or different shape. The buried features 1652 and the top features 1654 may be features of the same or different size in one or more dimension. The buried features 1652 and the top features 1654 may be offset in one or more lateral direction (e.g., along in the x-axis 1602, along the y-axis 1604, etc.). The buried features 1652 and the top features 1654 may be offset by a first lateral offset 1662, depicted along the x-axis 1602. The buried features 1652 and the top features 1654 may also or instead be offset by a second lateral offset, along the y-axis 1604. In the illustrative example, a negligible second lateral offset is depicted. The buried features 1652 and the top features 1654 may have negligible lateral offsets—e.g., the first lateral offset 1662 and the second lateral offset may be substantially zero. As sizes and shapes of the buried features 1652 and the top features 1654 may be different, the buried features 1652 and the top features 1654 may incompletely overlay even if the first lateral offset 1662 and the second lateral offset are substantially zero. The buried features 1652 and the top features 1654 may be partially overlapping, for example when the first lateral offset 1662 and the second lateral offset are smaller than half the size of the smallest of the buried features 1652 and the top features 1654. The buried features 1652 and the top features may be non-overlapping, for example when the first lateral offset 1662 and the second lateral offset are larger than the size of the largest of the buried features 1652 and the top features 1654.

The dashed rectangle 1650 may correspond to an SEM image of the example SEM target. The SEM image may contain areas (e.g., regions of pixels) which correspond to signals from the buried features 1652. The SEM image may contain areas (e.g., regions of pixels) which correspond to signals from the top features 1654. The SEM image may contain areas which contain signals which correspond to other layers of the example SEM target (e.g., the fill layer 1616, the adhesion layer 1612, etc.) which may be patterned or unpatterned. A measure of overlay may be determined based on the SEM image. The measure of overlay may be determined based on template matching or other image processing methods. The measure of overlay may measure characteristics of the SEM image corresponding to at least one of the first lateral offset 1662, the second lateral offset, or a combination thereof. The measure of overlay may depend on contrast, for example because template matching accuracy may depend on contrast levels determination of a measure of overlay may depend on contrast levels. The measure of overlay may be affected by beam tilt angle, where the beam tilt angle may interact with the recess space to change the measure of overlay from what would otherwise be expected.

A set-get overlay relationship may be determined based on the measure of overlay and knowledge of the first lateral offset 1662 and the second lateral offset. The first lateral offset 1662 may be known based on fabrication details, such as a design layout. The second lateral offset may be known based on fabrication details, such as a design layout. The set-get overlay relationship may be determined may on the intensity of various areas of the SEM image. The set-get overlay relationship may be determined based on multiple measurements of overlay for areas with different lateral offsets. The set-get overlay relationship may be affected by beam tilt angle. The set-get overlay relationship may also be affected by a recess depth of a top feature. By determining set-get overlay relationships for different recess depths and determining a relationship between them a beam tilt angle may be determined.

For each lateral direction, the set-get overlay relationship may be determined based on a fitted first order polynomial function, etc. The set-get overlay relationship may be plotted (for example as a scatter plot) for multiple values of known overlay (e.g., set overlay) and multiple measured values of overlay (e.g., get overlay). A slope and/or offset may be determined for the set-get overlay relationship for a given set of features (e.g., the measurement structure of FIGS. 13A and 13B with varying lateral offsets) of the SEM target. Multiple set-get overlay relationships may be determined for multiple measurable structural characteristics, for example corresponding to pitch in multiple areas (such as the areas 724 of FIG. 4).

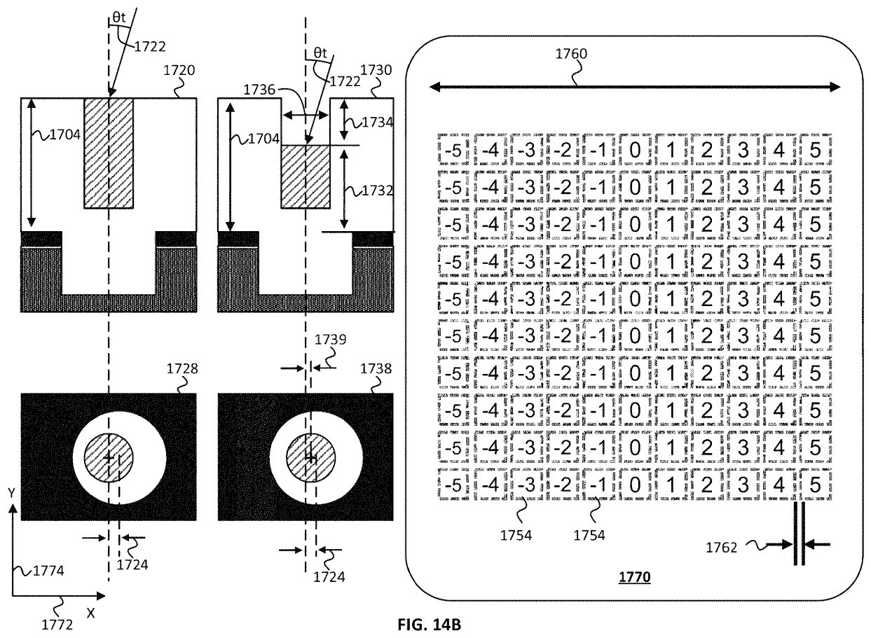

FIGS. 14A-14B depict tilt angle calibration features for a SEM target. FIG. 14A depicts cross-sectional views and substrate-plane views of tilt angle calibration features with various configurations and beam tilt angles. FIG. 14A depicts a cross-sectional view 1700 and a substrate-plane view 1708 (e.g., corresponding to an SEM image) of a tilt angle calibration feature with a negligible recess depth, negligible lateral offset, and a negligible beam tilt angle 1702. In the substate-plane view 1708, a hatched circle representing the top layer feature and a white circle representing the buried layer feature (at a buried depth 1704) are concentric about a shared center.

FIG. 14A depicts a cross-sectional view 1720 and a substrate-plane view 1728 of a tilt angle calibration feature with a negligible recess depth and negligible lateral offset (e.g., substantially similar to the tilt angle calibration feature depicted in the cross-sectional view 1700 and the substrate-plane view 1708), with a non-zero beam tilt angle, beam tilt angle 1722. In the substrate-plane view 1728, a hatched circle representing the top layer feature is centered laterally (along an x-axis 1772) on the top layer feature to which it corresponds. However, in the substrate-plane view 1728, a white circle representing the buried layer feature is offset laterally (along the x-axis 1772) from the buried layer feature to which it corresponds by a distance 1724. The distance 1724 may vary with depth (e.g., of the buried feature) and with beam tilt angle 1722.

FIG. 14A depicts a cross-sectional view 1730 and a substate-plane view 1738 of a tilt angle calibration feature with a non-zero recess depth for a selective recess and negligible lateral offset at a non-zero beam tilt angle, beam tilt angle 1722. In the substrate-plane view 1738, a hatched circle representing the top layer feature is offset laterally (along an x-axis 1772) from the top layer feature to which it corresponds by a distance 1739. Additionally, in the substrate-plane view 1738, a white circle representing the buried layer feature is offset laterally (along the x-axis 1772) from the buried layer feature to which it corresponds by a distance 1724. The distances 1739 and 1724 may vary with depth (e.g., of the buried feature) and with beam tilt angle 1722. The distance 1724 can be larger than the distance 1739 (e.g., in magnitude) because the distance 1724 corresponds to the buried feature layer with a larger depth than the top feature layer, which corresponds to the distance 1739.

FIG. 14A also depicts a cross-sectional view 1740 and a substrate-plane view 1748 of a tilt angle calibration feature with a non-zero recess depth for a non-selective recess and negligible lateral offsets at a non-zero beam tilt angle, beam tilt angle 1722. Additionally, in the substrate-plane view 1748, a white circle representing the buried layer feature is offset laterally (along the x-axis 1772) from the buried layer feature to which it corresponds by a distance 1724. The distances 1739 and 1724 in substrate-plane view 1748 may be substantially similar to the distance 1739 and 1724 in the substrate-plane view 1738, where the difference between the cross-sectional view 1730 and the cross-section view 1740 is the selectivity of the recess. A selective recess, as depicted in the cross-sectional view 1730, may involve recessed top layer features while a bulk or global substrate surface is not recessed, while an unselective recess, as depicted in the cross-sectional view 1740, may involve a locally recessed substrate surface. The area of the unselective recess may include one or more tilt angle calibration features. For example, a set of tilt angle calibration features with programmed overlay values may be included in one or more area of an unselective recess.

The cross-sectional views 1700, 1720, 1730 and 1740 are depicted with respect to a z-axis 1776 and the x-axis 1772. The substrate-plane views 1708, 1728, 1738, and 1748 are depicted with respect to the x-axis 1772 and a y-axis 1774. As with other generic axis described herein, the generic axes are provided for ease of description. In the cross-sectional views 1700, 1720, and 1730, buried features have a buried depth 1704. In the cross-sectional view 1740, the buried features have a buried depth of 1704, with respect to an unrecessed wafer surface 1742 and a buried depth of 1732 with respect to the local wafer surface. In the cross-sectional views 1730, top features have a recess depth 1734, a fill depth 1732 which is the difference between the buried depth 1704 and the recess depth 1734, a thickness 1737, and recesses have a recess width 1736. While the fill depth 1732 is depicted as the difference between a top of the top layer feature and the buried depth 1704 and the thickness 1737 of the top feature is depicted as the difference between the top of the top layer feature and a bottom of the top layer feature, the fill depth 1732 may instead be another equal to the thickness 1737 depending upon the relative depths of the top feature layer and the buried feature layer. For example, the buried features and the top features may be separated vertically by one or more layers, the bottom of the top feature layer may be co-planar with the top of the buried feature, the top features may extend vertically below the top of the buried feature, etc. Likewise, while the recess width 1736 is depicted as similar in width to the width of the top features, the recess width 1736 (e.g., a lateral extent of the recesses) may be larger or smaller than a width of the top feature (e.g., by a few nanometers). In both cross-sectional views 1720, 1730, and 1740 and substrate-plane views 1728, 1738, and 1748, the incident electron beam (e.g., of an SEM system) has a beam tilt angle 1722 of et.

FIG. 14B depicts pairs of tilt angle calibration features in an SEM target. FIG. 14B depicts the cross-sectional views 1720 and 1730, which are substantially similar except for the recess depth 1734, and their corresponding substrate-plane views 1728 and 1738. This pair of tilt angle calibration features are provided as exemplary features which may be contained withing an SEM target 1770 and which may be used to determine the beam tilt angle 1722.

The SEM target 1770 is comprised of areas 1754 separated by a separation distance 1762. The SEM target 1770 may be of size 1760 in one or more dimension. Each of the areas 1754 of the SEM target 1770 may comprise features (e.g., buried features and top features) with an overlay relationship (e.g., a set overlay). For illustrative purposes, the areas 1754 are labeled with overlay values, which may correspond to one or more lateral overlay offset. In the illustrative example, the areas 1754 are arranged in a rectilinear array (although other arrangements may be used as previously described) in which the areas 1754 of columns have a similar overlay value, which increases across each row. For example, overlay values of −5 nm to 5 nm in 1 nm steps may be used in both x-axis 1772 direction and y-axis 1774 direction. The areas 1754 in each row may have a consistent recess depth, which may vary between rows. For example, a first row may have a negligible recess depth (e.g., may correspond to the set of features of FIGS. 12A and 12B), while a second row may have a non-negligible recess depth (e.g., may correspond to the set of features of FIGS. 13A and 13B). Each of the rows may correspond to a different recess depth. Alternatively, two or more of the rows may be devoted to sets of features for measuring beam tilt angle while other rows of the SEM target 1770 may be devoted to features for measuring other parameters, such as resolution, contrast, overlay precision, etc. In the SEM target 1770, areas 1754 containing features with similar overlay values but different recess depths may be located substantially adjacently. Substantially adjacent may include adjacent with no intervening features, adjacent with intervening fields or features, adjacent with intervening boundaries, interspersed, etc. The SEM target 1770 may comprise areas 1754 which contain features which are substantially similar, with or without variations in recess depth and overlay value between the areas. The SEM target 1770 may comprise areas 1754 which contain a variety of features, such as areas 1754 (e.g., two or more rows) which contain a first set of features (e.g., a first pattern) and other areas 1754 (e.g., two or more rows) which contain a second set of features (e.g., a second pattern). The SEM target 1770 may comprise areas 1754 with various patterns, such as two-dimensional patterns, one-dimensional patterns, patterns with different feature sizes, patterns with different feature shapes (including different shapes for buried features and top features), etc. The SEM target 1770 may comprise areas 1754 which are substantially all devoted to measurement of set-get overlay relationships.

The multiple of areas 1754 when taken together may comprise an overlay target. An overlay target may comprise features which may be used to measure a set-get overlay relationship. The features which comprise an overlay target may be features which are substantially similar, but which vary in overlay (e.g., set overlay) such as over a range. For example, the areas 1754 of a row may comprise an overlay target with overlay values which vary between-5 nm and 5 nm. The features of an overlay target may comprise features with similar buried depth, recess depth, CD, pitch, etc. The SEM target 1770 may comprise multiple overlay targets which are substantially similar to one another, but which vary in recess depth—for example a first overlay target with a negligible recess depth and a second overlay target with a non-negligible recess depth (such as the recess depth 1744). Multiple set-get relationships may be determined based on multiple overlay targets.

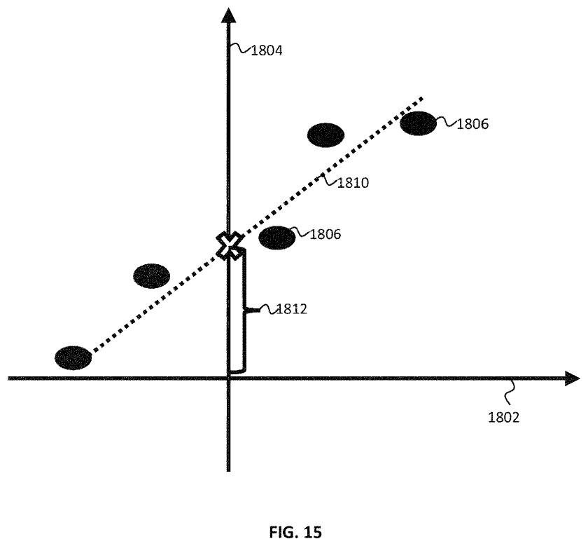

FIG. 15 depicts an example graph of a set-get relationship between overlay acquired using tilt angle calibration features of an SEM target. The SEM images can be acquired from SE (secondary electron) detection (e.g., via an SE channel of an SEM) and BSE (back scatter electron) detection (e.g., via a BSE channel of an SEM), including simultaneously. The SE channel images may be used to detect top layer pattern features, while BSE channel images may be used to detect the lower layer pattern features (e.g., buried features). By combining the information from both images, an overlay between top and bottom layer patterns may be derived. FIG. 15 depicts points 1806 which with values of set overlay (e.g., overlay as fabricated) along an x-axis 1802 and with values of get overlay (e.g., overlay as measured) along an x-axis 1804 for an overlay target. Each of the points 1806 corresponds to overlay measured for a beam tilt structure, such as those depicted in FIGS. 12A, 12B, 13A, 13B, and 14. A dashed line 1810 represents a linear fit to the points 1806 and may represent the set-get overlay relationship for the beam tilt structure. Although only one measurement is depicted for each of the set overlay values (e.g., overlay as fabricated) multiple measurements may be performed, including multiple measurements of each beam tilt structure or measurements of multiple beam tilt structures with the same set overlay values. An intercept 1812 may be determined based on the linear fit. Fits other than linear fits may be used. Linear fits may be optimized using different fitting optimizations, such as least mean squared, linear regression, etc. The intercept 1812 may be related to beam tilt angle and recess depth, including via a geometric relationship. The value of the intercept 1812 may be related to beam tilt angle and depth by using Equation 1, below, or similar:

$$intercept = {OV}^{true} + d * tan {θ}_{t} \qquad ( 1 )$$

where intercept is the y-axis intercept for a set-get overlay relationship for a beam tilt structure, OV^{true} may be a true overlay (e.g., the as-fabricated overlay as determined based on wafer manufacture and not design layout), d is the depth for the beam tilt structure, and Ot is the beam tilt angle.

For example, a beam tilt angle may be determined based on the SEM target structure of FIG. 14B. For the beam tilt calibration features represented by the cross-sectional view 1700 with programed overlay value ranging from −5 nm, −4 nm, . . . to +5 nm, the intercept can be expressed as given by Equation 2, below:

$${intercept}_{1} = {OV}^{true} + d 1 * tan {θ}_{t} \qquad ( 2 )$$

where intercept₁ is the intercept for the set-get overlay relationship determined based on the beam tilt calibration features with the programmed overlay values and where d1 is the buried depth 1704. For the beam tilt calibration features represented by the cross-sectional view 1730 with programed overlay value ranging from −5 nm, −4 nm, . . . to +5 nm, the intercept can be expressed as given by Equation 3, below:

$${intercept}_{2} = {OV}^{true} + d 2 * tan {θ}_{t} \qquad ( 3 )$$

where intercept₂ is the intercept for the set-get relationship determined based on the beam tilt calibration features with the programmed overlay values and recess depth and where d2 is the recess depth 1734.

Given the above, the beam tilt angle may then be solved, such as by using Equation 4, below:

$${θ}_{t} = {tan}^{- 1} ( \frac{{intercept}_{1} - {intercept}_{2}}{d 1 - d 2} ) \qquad ( 4 )$$

where beam tilt angle may be determined based on the difference in depths between the top features and the buried features when the top features are not recessed and when the top features are recessed and based on the difference in the intercepts for the set-get relationships of the programmed overlay values for the corresponding beam tilt angle calibration features. Using more than two sets of beam tilt angle calibration features (e.g., three or more sets of beam tilt angle calibration features with varying recess depths) for the beam tilt angle calibration may be improve the tilt angle calibration robustness, accuracy, etc. Using two sets of beam tilt angle calibration features (e.g., a set of beam tilt angle calibration features with negligible recess depth and a set of beam tilt angle calibration features with a non-zero recess depth) may provide sufficient beam tilt angle calibration while minimizing fabrication process complexity and size for the beam tilt angle features.

Beam tilt angle may be characterized by beam tilt angle along multiple axes. Based on the above method, beam tilt angle may be calibrated for each lateral direction. For example, tilt angle along x direction

$${θ}_{t}^{x}$$

can be calibrated with set-get x overlay relation, while tilt angle along y direction θₜ^{y} can be calibrated with set-get y overlay relation. Based on the tilt angle in both x and y direction, the beam tilt angle azimuth direction can be calculated, such as by determining

$${tan}^{- 1} ( \frac{{θ}_{t}^{y}}{{θ}_{t}^{x}} ) .$$

By determining intercept and the depth the beam tilt angle can be solved for empirically, as the set-get overlay relationships of Equation 1 can be used to generate two or more equations and solve for Ot. In this manner, the true overlay (e.g., OV^{true}) may be substituted for in the determination and may be neglected. As true overlay may be difficult to obtain, the determination based on measurable characteristics of tilt angle calibration features is advantageous. In some embodiments, the depth d and may be measured as accurately as possible, including by nondestructive techniques, including ellipsometer, reflectometer and AFM (Atomic Force Microscope), in order to determine a beam tilt angle.

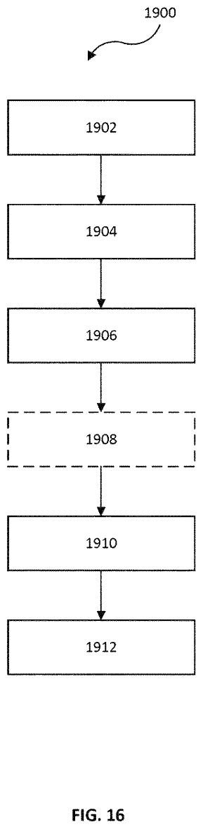

FIG. 16 illustrates a method of SEM target generation. Each of these operations is described in detail below. The operations of method 1900 presented below are intended to be illustrative. In some embodiments, method 1900 may be accomplished with one or more additional operations not described, and/or without one or more of the operations discussed. Additionally, the order in which the operations of method 1900 are illustrated in FIG. 16 and described below is not intended to be limiting. In some embodiments, one or more portions of method 1900 may be implemented (e.g., by simulation, modeling, etc.) in one or more processing devices (e.g., one or more processors). The one or more processing devices may include one or more devices executing some or all of the operations of method 1900 in response to instructions stored electronically on an electronic storage medium. The one or more processing devices may include one or more devices configured through hardware, firmware, and/or software to be specifically designed for execution of one or more of the operations of method 1900, for example.

At an operation 1902, a fabrication specification is acquired. The fabrication specification may correspond to a design layout. The fabrication specification may include feature depth. The fabrication specification may include identification of critical features. The fabrication specification may include materials for features. The fabrication specification may include SEM imaging parameters, such as LE, magnification, etc.

At an operation 1904, a buried depth is determined. The buried depth may be determined based on a feature depth from the fabrication specification. The buried depth may be determined by nondestructive techniques, including ellipsometer, reflectometer and AFM (Atomic Force Microscope)

At an operation 1906, multiple feature sizes, programmed overlay and/or shapes are determined. The feature sizes and programmed overlay may be determined based on the fabrication specification. The feature sizes may be determined based on a resolution limit of the fabrication specification. The feature shapes may be determined based on feature shapes from the fabrication specification.

At an operation 1908, an alignment landing energy (LE) may be optionally determined. Beam tilt angle may vary based on LE even if all other SEM parameters are held constant. The alignment LE may be determined based on the fabrication specification, such as by selecting the LE most commonly used for overlay metrology

At an operation 1910, a SEM target design is generated based on the fabrication specification. The SEM target may comprise areas containing features, such as described in reference to FIGS. 5A and 5B, used to measure contrast and/or resolution. The SEM target may comprise areas containing features, such as described in reference to FIGS. 9A and 9B, used to measure overlay precision. The SEM target may comprise areas containing features, such as described in reference to FIGS. 12A, 12B, 13A, and 13B, used to measure beam tilt angle. The SEM target may comprise areas which comprise one or more overlay targets. The SEM target may contain areas which have different measurable structural characteristics, such as recess depth, buried depth, pitch, etc. The SEM target may contain a variety of measurable structural characteristics, which may cover a range of values such as from expected resolution limit (which may be smaller than a CD) to a largest fabrication feature size.

At an operation 1912, performance indicators may be determined based on one or more SEM images of a fabricated SEM target design. The performance indicators may be determined for one or more LEs, where an SEM image may be acquired for each of the one or more LEs. The performance indicators may be determined by comparing measured parameters of the SEM images (e.g., contrast, resolution, overlay precision, get overlay, etc.) to modeled or otherwise expected values for parameters of the SEM image. The performance indicators may be used to determine an indication of SEM performance. The performance indicators may be used to align the SEM system.

As described above, method 1900 (and/or the other methods and systems described herein) is configured for SEM target generation.

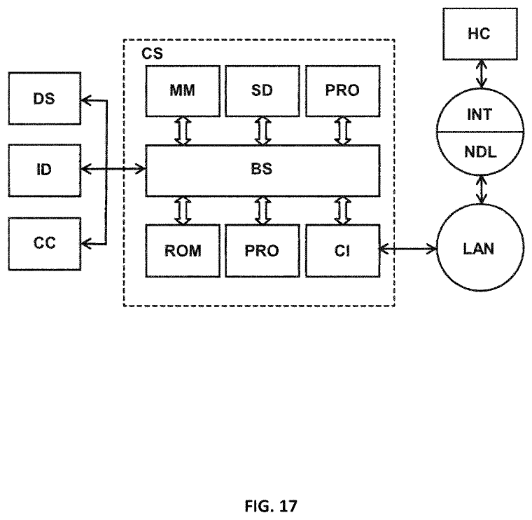

FIG. 17 is a diagram of an example computer system CS that may be used for one or more of the operations described herein. Computer system CS includes a bus BS or other communication mechanism for communicating information, and a processor PRO (or multiple processors) coupled with bus BS for processing information. Computer system CS also includes a main memory MM, such as a random-access memory (RAM) or other dynamic storage device, coupled to bus BS for storing information and instructions to be executed by processor PRO. Main memory MM also may be used for storing temporary variables or other intermediate information during execution of instructions by processor PRO. Computer system CS further includes a read only memory (ROM) ROM or other static storage device coupled to bus BS for storing static information and instructions for processor PRO. A storage device SD, such as a magnetic disk or optical disk, is provided and coupled to bus BS for storing information and instructions.

Computer system CS may be coupled via bus BS to a display DS, such as a cathode ray tube (CRT) or flat panel or touch panel display for displaying information to a computer user. An input device ID, including alphanumeric and other keys, is coupled to bus BS for communicating information and command selections to processor PRO. Another type of user input device is cursor control CC, such as a mouse, a trackball, or cursor direction keys for communicating direction information and command selections to processor PRO and for controlling cursor movement on display DS. This input device typically has two degrees of freedom in two axes, a first axis (e.g., x) and a second axis (e.g., y), that allows the device to specify positions in a plane. A touch panel (screen) display may also be used as an input device.

In some embodiments, portions of one or more methods described herein may be performed by computer system CS in response to processor PRO executing one or more sequences of one or more instructions contained in main memory MM. Such instructions may be read into main memory MM from another computer-readable medium, such as storage device SD. Execution of the sequences of instructions included in main memory MM causes processor PRO to perform the process steps (operations) described herein. One or more processors in a multi-processing arrangement may also be employed to execute the sequences of instructions contained in main memory MM. In some embodiments, hard-wired circuitry may be used in place of or in combination with software instructions. Thus, the description herein is not limited to any specific combination of hardware circuitry and software.

The term “computer-readable medium” and/or “machine readable medium” as used herein refers to any medium that participates in providing instructions to processor PRO for execution. Such a medium may take many forms, including but not limited to, non-volatile media, volatile media, and transmission media. Non-volatile media include, for example, optical or magnetic disks, such as storage device SD. Volatile media include dynamic memory, such as main memory MM. Transmission media include coaxial cables, copper wire and fiber optics, including the wires that comprise bus BS. Transmission media can also take the form of acoustic or light waves, such as those generated during radio frequency (RF) and infrared (IR) data communications. Computer-readable media can be non-transitory, for example, a floppy disk, a flexible disk, hard disk, magnetic tape, any other magnetic medium, a CD-ROM, DVD, any other optical medium, punch cards, paper tape, any other physical medium with patterns of holes, a RAM, a PROM, and EPROM, a FLASH-EPROM, any other memory chip or cartridge. Non-transitory computer readable media can have instructions recorded thereon. The instructions, when executed by a computer, can implement any of the operations described herein. Transitory computer-readable media can include a carrier wave or other propagating electromagnetic signal, for example.

Various forms of computer readable media may be involved in carrying one or more sequences of one or more instructions to processor PRO for execution. For example, the instructions may initially be borne on a magnetic disk of a remote computer. The remote computer can load the instructions into its dynamic memory and send the instructions over a telephone line using a modem. A modem local to computer system CS can receive the data on the telephone line and use an infrared transmitter to convert the data to an infrared signal. An infrared detector coupled to bus BS can receive the data carried in the infrared signal and place the data on bus BS. Bus BS carries the data to main memory MM, from which processor PRO retrieves and executes the instructions. The instructions received by main memory MM may optionally be stored on storage device SD either before or after execution by processor PRO.

Computer system CS may also include a communication interface CI coupled to bus BS. Communication interface CI provides a two-way data communication coupling to a network link NDL that is connected to a local network LAN. For example, communication interface CI may be an integrated services digital network (ISDN) card or a modem to provide a data communication connection to a corresponding type of telephone line. As another example, communication interface CI may be a local area network (LAN) card to provide a data communication connection to a compatible LAN. Wireless links may also be implemented. In any such implementation, communication interface CI sends and receives electrical, electromagnetic, or optical signals that carry digital data streams representing various types of information.

Network link NDL typically provides data communication through one or more networks to other data devices. For example, network link NDL may provide a connection through local network LAN to a host computer HC. This can include data communication services provided through the worldwide packet data communication network, now commonly referred to as the “Internet” INT. Local network LAN (Internet) may use electrical, electromagnetic, or optical signals that carry digital data streams. The signals through the various networks and the signals on network data link NDL and through communication interface CI, which carry the digital data to and from computer system CS, are exemplary forms of carrier waves transporting the information.

Computer system CS can send messages and receive data, including program code, through the network(s), network data link NDL, and communication interface CI. In the Internet example, host computer HC might transmit a requested code for an application program through Internet INT, network data link NDL, local network LAN, and communication interface CI. One such downloaded application may provide all or part of a method described herein, for example. The received code may be executed by processor PRO as it is received, and/or stored in storage device SD, or other non-volatile storage for later execution. In this manner, computer system CS may obtain application code in the form of a carrier wave.

Embodiments of the present disclosure can be further described by the following clauses.
1. A method for evaluating a scanning electron microscope (SEM) system, comprising:
accessing an SEM image of two or more sets of overlay targets,
wherein each set of overlay targets comprises buried features and top features, the buried features at a buried depth,
wherein, in at least one of the two or more sets of overlay targets, the top features are recessed, each of the recesses having a corresponding recess depth,
wherein the recess depths for the top features of the two or more sets of overlay targets are different; and
determining a beam tilt angle of a SEM system based on the SEM images of the two or more sets of overlay targets.
2. The method of clause 1, wherein determining the beam tilt angle comprises determining the beam tilt angle based on set-get relationships for overlay determined for the two or more sets of overlay targets.
3. The method of clause 2, wherein determining the beam tilt angle based on the set-get relationships for overlay comprises:
obtaining measurements of at least one of the recess depths, a difference between the recess depths, or a combination thereof;
determining intercept values based on fitting of the set-get relationships for overlay for the two or more sets of overlay targets; and
determining the beam tilt angle based on the intercept values and the measurements of at least one of recess depths, a difference between the recess depths, or a combination thereof.
4. The method of clause 1, wherein accessing the SEM image further comprises accessing additional SEM images captured at different landing energies and wherein determining the beam tilt angle further comprises determining beam tilt angles corresponding to the different landing energies based on the SEM images captured at different landing energies.
5. The method of clause 4, wherein determining the beam tilt angles corresponding to the different landing energies comprises determining the beam tilt angles based on set-get relationships for overlay determined for the two or more sets of overlay targets at the different landing energies.
6. The method of clause 5, wherein determining the beam tilt angles based on the set-get relationships for overlay determined for the two or more sets of overlay targets at the different landing energies comprises:
obtaining measurements of at least one of the recess depths, a difference between the recess depths, or a combination thereof;
determining intercept values for the different landing energies based on fitting of the set-get relationships for overlay for the two of more sets of overlay targets at different landing energies; and
determining the beam tilt angles corresponding to the different landing energies based on the intercept values for the different landing energies and the measurements of at least one of recess depths, a difference between the recess depths, or a combination thereof.
7. The method of clause 4, further comprising adjusting SEM alignment based on at least one of the beam tilt angles corresponding to the different landing energies.
8. The method of clause 1, further comprising adjusting SEM alignment based on the beam tilt angle.
9. The method of clause 1, wherein the SEM system comprises a secondary electron detector.
10. The method of clause 1, wherein the SEM image is generated by detection of secondary electrons.
11. The method of clause 1, wherein the SEM system comprises a backscattering electron detector.
12. The method of clause 1, wherein the SEM image is generated by detection of backscattered electrons.
13. The method of clause 1, wherein the SEM image is generated by detection of secondary electrons and backscattered electrons.
14. The method of clause 1, wherein the two or more sets of overlay targets are adjacent to one another.
15. A method for evaluating a scanning electron microscope (SEM) system, comprising:
accessing an SEM image of a plurality of cells of containing various patterns,
wherein each cell within the plurality comprises a pattern having a corresponding pitch,
wherein the pattern comprises buried features at a buried depth, and
wherein the SEM image comprises an image of the plurality of cells within a single field of view (FOV); and
determining, for at least one of the cells within the single FOV, a relationship between the pitch thereof and at least one of contrast, resolution, or a combination thereof.
16. The method of clause 15, further comprising comparing the determined relationship between the pitch and the at least one of contrast, resolution, or the combination thereof for said at least one of the cells within the single FOV to a simulation of the relationship between pitch and contrast, resolution, or the combination thereof to obtain information on alignment of the SEM.
17. The method of clause 15, wherein determining the relationship between the pitch and the at least one of contrast, resolution, or a combination thereof comprises determining at least one of contrast, resolution, or a combination thereof for multiple of the plurality of cells, wherein the corresponding pitch varies among the multiple of the plurality of cells.
18. The method of clause 15, further comprising determining a performance indicator for SEM beam quality based on the relationship between the pitch and the at least one of contrast, resolution, or the combination thereof.
19. The method of clause 15, wherein accessing the SEM image comprises accessing SEM images captured at different landing energies and wherein determining the relationship between the pitch and the at least one of contrast, resolution, or a combination thereof determining relationships between pitch and at least one of contrast, resolution, or a combination thereof for the different landing energies.
20. The method of clause 19, further comprising determining a performance indicator for SEM beam quality based on the relationships between the pitch and the at least one of contrast, resolution, or the combination thereof for the different landing energies.
21. The method of clause 18 or 20, further comprising adjusting alignment of the SEM based on the at least one SEM performance indicator.
22. The method of clause 19, wherein the corresponding pitch for each cell is selected based on a simulation such that the relationship between the pitch and the at least one of contrast, resolution, or a combination thereof varies between the different landing energies.
23. The method of clause 15, wherein determining contrast comprises determining a ratio between intensity change and number of pixels.
24. A method for evaluating a scanning electron microscope (SEM) system comprising:
accessing SEM images of a plurality of cells containing various patterns,
wherein each cell within the plurality comprises a pattern having a corresponding pitch,
wherein the pattern comprises buried features and top features separated by a buried depth,
wherein the buried features and the top features are separated by an overlay offset in a direction perpendicular to the buried depth,
wherein the corresponding pitch varies among at least some of the plurality of cells, and
wherein the SEM images comprise images of the plurality of cells within a single field of view (FOV); and
determining a relationship between pitch and overlay precision based on the SEM images of the plurality of cells having corresponding pitches.
25. The method of clause 24, further comprising comparing the relationship between the pitch and the overlay precision to a simulation of the relationship between the pitch and the overlay precision.
26. The method of clause 24, further comprising determining a performance indicator for SEM beam quality based on the relationship between the pitch and the overlay precision.
27. The method of clause 24, wherein accessing SEM images comprises accessing SEM images captured at different landing energies and wherein determining the relationship between the pitch and the overlay precision comprises determining relationships between pitch and overlay precision for the different landing energies.
28. The method of clause 27, further comprising determining a performance indicator for SEM beam quality based on the relationships between the pitch and the overlay precision for the different landing energies.
29. The method of clause 26 or 28, further comprising adjusting alignment of the SEM based on the performance indicator.
30. The method of clause 27, wherein the corresponding pitch for each cell is selected based on a simulation such that the relationship between the pitch and the overlay precision varies between landing energies.
31. The method of clause 15 or 24, wherein adjacent cells comprise patterns having different corresponding pitches.
32. One or more non-transitory, machine-readable medium having instruction thereon, the instructions when executed by a processor being configured to perform the method of any one of clauses 1 to 31.
33. A scanning electron microscope (SEM) target for evaluation of an SEM system comprising:
a plurality of areas on a wafer, each area containing buried features, the buried features having a measurable structural characteristic,
wherein the buried features are buried under top features, the buried features having corresponding buried depths,
wherein at least some of the top features are recessed, the top features having corresponding recess depths,
wherein a first set of areas comprise a first set of overlay targets and a second set of areas comprise a second set of overlay targets,
wherein the recess depth for the first set of overlay targets and the recess depth for the second set of overlay targets are different, and
wherein the first overlay target and the second overlay target are adjacent to one another.
34. The SEM target of clause 33, wherein the top features and the buried features are of a substantially similar size and a substantially similar shape.
35. The SEM target of clause 33, wherein recessed regions of the top features have substantially similar sidewall angles (SWA).
36. The SEM target of clause 33, wherein the recess depths of the top features in a given area are substantially similar.
37. The SEM target of clause 33, wherein the first set of areas comprising the first set of overlay targets and the second set of areas comprising the second set of overlay targets each comprises a set of areas for which the top features have varying lateral offsets with respect to the buried features in a direction perpendicular to the recess depths.
38. The SEM target of clause 37, wherein the varying lateral offsets of the first set of areas comprising the first set of overlay targets and the varying lateral offsets the second set of areas comprising the second set of overlay targets are substantially similar.
39. The SEM target of clause 33, wherein set-get relationships for overlay can be determined for the first set of overlay targets and the second set of overlay targets.
40. The SEM target of clause 33, wherein intercepts of a set-get relationship for overlay can be determined for the first set of overlay targets and for the second set of overlay targets.
41. The SEM target of clause 33, wherein the top features of the first set of overlay targets are not recessed.
42. The SEM target of clause 41, wherein the recess depth for the first set of overlay targets is substantially zero.
43. The SEM target of clause 41, wherein the recess depth for the second set of overlay targets is measurable by nondestructive measurement techniques.
44. The SEM target of clause 41, wherein the recess depth of the second set of overlay targets is greater than a tenth of the buried depth of the buried features
45. The SEM target of clause 41, wherein the recess depth of the second set of overlay targets is greater than 10 nanometers.
46. The SEM target of clause 41, wherein the recess depth of the second set of overlay targets is substantially equal to the buried depth of the buried features.
47. The SEM target of clause 41, wherein the recess depth of the second set of overlay targets is greater than 200 nanometers.
48. The SEM target of clause 33, wherein the buried depth corresponds to a depth for SEM alignment.
49. The SEM target of clause 48, wherein the buried depths correspond to a depth for SEM alignment based on backscattering electrons.
50. The SEM target of clause 33, wherein at least some of the recess depths are fabricated by at least partially etching areas of the wafer corresponding to the top features.
51. The SEM target of clause 33, wherein at least some of the recess depths are fabricated by partially filling recessed areas of the wafer corresponding to the top features.
52. A method of fabricating the SEM target of any one of clauses 33 to 51.
53. One or more non-transitory, machine-readable medium having instructions thereon, the instructions when executed by a processor being configured to fabricate the SEM target of any one of clauses 33 to 51.

While the concepts disclosed herein may be used for manufacturing with a substrate such as a silicon wafer, it shall be understood that the disclosed concepts may be used with any type of manufacturing system (e.g., those used for manufacturing on substrates other than silicon wafers).

In addition, the combination and sub-combinations of disclosed elements may comprise separate embodiments. For example, one or more of the operations described above may be included in separate embodiments, or they may be included together in the same embodiment.

The descriptions above are intended to be illustrative, not limiting. Thus, it will be apparent to one skilled in the art that modifications may be made as described without departing from the scope of the claims set out below.

1. One or more non-transitory, machine-readable medium having instructions therein or thereon, the instructions, when executed by at least one processor, are configured to cause the at least one processor to at least:
access one or more scanning electron microscope (SEM) image of two or more sets of overlay targets,
wherein each set of overlay targets comprises buried features and top features, the buried features at a buried depth,
wherein, in at least one of the two or more sets of overlay targets, the top features are recessed, each of the recesses having a corresponding recess depth, and
wherein the recess depths for the top features of the two or more sets of overlay targets are different; and
determine a beam tilt angle of a SEM system based on the one or more SEM images of the two or more sets of overlay targets.

2. The medium of claim 1, wherein the instructions configured to cause the at least one processor to determine the beam tilt angle are further configured to cause the at least one processor to determine the beam tilt angle based on set-get relationships for overlay determined for the two or more sets of overlay targets.

3. The medium of claim 2, wherein the instructions configured to cause the at least one processor to determine the beam tilt angle based on the set-get relationships for overlay are further configured to cause the at least one processor to:
obtain measurements of at least one of the recess depths, a difference between the recess depths, or a combination thereof;
determine intercept values based on fitting of the set-get relationships for overlay for the two or more sets of overlay targets; and
determine the beam tilt angle based on the intercept values and the measurements of at least one of recess depths, a difference between the recess depths, or a combination thereof.

4. The medium of claim 1, wherein the instructions configured to cause the at least one processor to access the one or more SEM images are further configured to cause the at least one processor to access one or more additional SEM images captured at different landing energies and wherein the instructions configured to cause the at least one processor to determine the beam tilt angle are further configured to cause the at least one processor to determine beam tilt angles corresponding to the different landing energies based on the one or more SEM images captured at different landing energies.

5. The medium of claim 4, wherein the instructions configured to cause the at least one processor to determine the beam tilt angles corresponding to the different landing energies are further configured to cause the at least one processor to determine the beam tilt angles based on set-get relationships for overlay determined for the two or more sets of overlay targets at the different landing energies.

6. The medium of claim 5, wherein the instructions configured to cause the at least one processor to determine the beam tilt angles based on the set-get relationships for overlay determined for the two or more sets of overlay targets at the different landing energies are further configured to cause the at least one processor to:
obtain measurements of at least one of the recess depths, a difference between the recess depths, or a combination thereof;
determine intercept values for the different landing energies based on fitting of the set-get relationships for overlay for the two of more sets of overlay targets at different landing energies; and
determine the beam tilt angles corresponding to the different landing energies based on the intercept values for the different landing energies and the measurements of at least one of the recess depths, a difference between the recess depths, or a combination thereof.

7. The medium of claim 4, wherein the instructions are further configured to cause the at least one processor to adjust SEM alignment based on at least one of the beam tilt angles corresponding to the different landing energies.

8. The medium of claim 1, wherein the instructions are further configured to cause the at least one processor to adjust SEM alignment based on the beam tilt angle.

9. The medium of claim 1, wherein the SEM system comprises a secondary electron detector.

10. The medium of claim 1, wherein the SEM image is generated by detection of secondary electrons.

11. The medium of claim 1, wherein the SEM system comprises a backscattering electron detector.

12. The medium of claim 1, wherein the SEM image is generated by detection of backscattered electrons.

13. The medium of claim 1, wherein the SEM image is generated by detection of secondary electrons and backscattered electrons.

14. The medium of claim 1, wherein the two or more sets of overlay targets are adjacent to one another.

15. One or more non-transitory, machine-readable medium having instructions therein or thereon, the instructions, when executed by at least one processor, are configured to cause the at least one processor to at least:
access a scanning electron microscope (SEM) image of a plurality of cells containing various patterns,
wherein each cell within the plurality of cells comprises a pattern having a corresponding pitch,
wherein the pattern comprises buried features at a buried depth, and
wherein the SEM image comprises an image of the plurality of cells within a single field of view (FOV); and
determine, for at least one of the cells within the single FOV, a relationship between the pitch thereof and contrast, resolution, or both contrast and resolution.

16. The medium of claim 15, wherein the instructions are further configured to cause the at least one processor to compare the determined relationship between the pitch and contrast, resolution, or both contrast and resolution for the at least one of the cells within the single FOV to a simulation of the relationship between pitch and contrast, resolution, or both contrast and resolution to obtain information on alignment of the SEM.

17. The medium of claim 15, wherein the instructions configured to cause the at least one processor to determine the relationship between the pitch and contrast, resolution, or both resolution and contrast are further configured to cause the at least one processor to determine contrast, resolution, or both contrast and resolution for multiple of the plurality of cells, wherein the corresponding pitch varies among the multiple of the plurality of cells.

18. One or more non-transitory, machine-readable medium having instructions therein or thereon, the instructions, when executed by at least one processor, are configured to cause the at least one processor to at least:
access scanning electron microscope (SEM) images of a plurality of cells containing various patterns,
wherein each cell within the plurality comprises a pattern having a corresponding pitch,
wherein the pattern comprises buried features and top features separated by a buried depth,
wherein the buried features and the top features are separated by an overlay offset in a direction perpendicular to the buried depth,
wherein the corresponding pitch varies among at least some of the plurality of cells, and
wherein the SEM images comprise images of the plurality of cells within a single field of view (FOV); and
determine a relationship between pitch and overlay precision based on the SEM images of the plurality of cells having corresponding pitches.

19. The medium of claim 18, wherein the instructions are further configured to cause the at least one processor to compare the relationship between the pitch and the overlay precision to a simulation of the relationship between the pitch and the overlay precision.

20. The medium of claim 18, wherein the instructions are further configured to cause the at least one processor to determine a performance indicator for SEM beam quality based on the relationship between the pitch and the overlay precision.
